(19) United States
(12) Patent Application Publication
(10) Pub. No.: US 2026/0173700 A1
(43) Pub. Date: Jun. 18, 2026

(54) DISPLAY PANEL AND DISPLAY APPARATUS

(71) Applicants: Hefei Visionox Electronics Co., Ltd., Hefei (CN); Hefei Visionox Technology Co., Ltd., Hefei (CN); Visionox Technology Inc., Suzhou (CN)

(72) Inventors: Yuan YAO, Hefei (CN); Zhiwei ZHOU, Hefei (CN); Aihua XUE, Hefei (CN); Chaoran QIN, Hefei (CN)

(73) Assignees: Hefei Visionox Electronics Co., Ltd., Hefei (CN); Hefei Visionox Technology Co., Ltd., Hefei (CN); Visionox Technology Inc., Suzhou (CN)

(21) Appl. No.: 19/419,885

(22) Filed: Dec. 15, 2025

Related U.S. Application Data
(63) Continuation of application No. PCT/CN2025/131387, filed on Oct. 30, 2025.

(30) Foreign Application Priority Data
Dec. 13, 2024 (CN) 202411847111.6

(51) Int. Cl. H10K 59/35; H10K 59/122; H10K 59/123; H10K 59/124; H10K 59/40; H10K 59/80

(52) U.S. Cl. CPC H10K 59/353; H10K 59/122; H10K 59/123; H10K 59/124; H10K 59/352; H10K 59/40; H10K 59/8723

(57) ABSTRACT

A display panel and a display apparatus. The display panel includes: a base plate; a light-emitting device including a first electrode, a light-emitting layer arranged at a side of the first electrode away from the base plate, and a second electrode arranged at a side of the light-emitting layer away from the base plate; and a touch electrode located at a side of the light-emitting device away from the base plate and including a touch portion, in which at least one light-emitting device includes at least two sub-devices, the first electrodes of the sub-devices within the light-emitting device are electrically interconnected, and at least a portion of an orthographic projection of the touch portion on the base plate is located between orthographic projections of light-emitting areas of adjacent two sub-devices in a same light-emitting device on the base plate.

### CROSS REFERENCE TO RELATED APPLICATION

The present application is a continuation application of International Application No. PCT/CN2025/131387, filed on Oct. 30, 2025, which claims priority to Chinese Patent Application No. 202411847111.6 filed on Dec. 13, 2024, both of which are incorporated herein by reference in their entireties.

### TECHNICAL FIELD

The present application relates to the field of display technology, and particularly to a display panel and a display apparatus.

### BACKGROUND

Planar display apparatus based on Organic Light Emitting Diode (OLED) and Light Emitting Diode (LED), etc., are widely used in cell phones, TVs, notebook computers, desktop computers, and other consumer electronic products due to their high image quality, power saving, thin body and wide range of applications, and have become the mainstream of the display apparatus. In traditional preparation process of display panel, fine metal mask (FMM) technology is commonly used to pattern light-emitting pixels. FMM technology is well developed and widely used in mass production. However, FMM technology suffers from limitations such as restricted precision, high development costs, and long development cycles. Maskless technology eliminates the constraints of conventional OLED processes on display screen size, resolution, and other panel performance metrics, offering advantages such as high performance, full-size scalability, and agile delivery. Reference is made to patent applications No. CN118251982A, CN115666161A, CN116648095A, CN117062489A, CN117580403A, CN118678743A, CN118660490A, CN118678724A, CN118678806A, CN118742084A, and CN118946184A for related content of maskless technology.

However, the process performance of current OLED display products requires improvement.

### SUMMARY

Embodiments of the present application provide a display panel and a display apparatus, aiming to improve the touch performance of the display panel.

Some embodiments of a first aspect of the present application provide a display panel, including: a base plate; a light-emitting device arranged at one side of the base plate and including a first electrode, a light-emitting layer arranged at a side of the first electrode away from the base plate, and a second electrode arranged at a side of the light-emitting layer away from the base plate; and a touch electrode located at a side of the light-emitting device away from the base plate and including a touch portion, in which at least one light-emitting device includes at least two sub-devices, the first electrodes of the sub-devices within the light-emitting device are electrically interconnected, and at least a portion of an orthographic projection of the touch portion on the base plate is located between orthographic projections of light-emitting areas of adjacent two sub-devices in a same light-emitting device on the base plate.

Some embodiments of a second aspect of the present application provide a display apparatus including the display panel of any of the above embodiments.

The display panel according to the embodiments of the present application includes the base plate, the light-emitting device, and the touch electrode. The light-emitting device is arranged at one side of the base plate and includes the first electrode, the light-emitting layer arranged at the side of the first electrode away from the base plate, and the second electrode arranged at the side of the light-emitting layer away from the base plate. The light-emitting device may have a light-emitting area, and the light-emitting device within the light-emitting area may emit light and display.

At least one light-emitting device may include at least two sub-devices, and the first electrodes of the sub-devices within the light-emitting device may be electrically interconnected, thereby facilitating controlling the light emission of the sub-devices within the light-emitting device. By dividing at least one light-emitting device into at least two sub-devices, when some sub-devices in the light-emitting device exhibit poor light emission, some other sub-devices in the light-emitting device can still achieve satisfactory light emission and display, so that the light-emitting device as a whole can continue to emit light, thereby effectively enhancing the operational reliability of the light-emitting device.

The touch electrode is located at the side of the light-emitting device away from the base plate and may be configured to achieve the touch function of the display panel. The touch electrode includes the touch portion, and at least a portion of the orthographic projection of the touch portion on the base plate is located between the orthographic projections of the light-emitting areas of adjacent two sub-devices in a same light-emitting device on the base plate, so that the touch portion can extend over the gap between the light-emitting areas of adjacent two sub-devices in a same light-emitting device. In this way, the touch portion is less likely to block the light emission and display of the light-emitting device, and the space within the display panel can be effectively utilized to accommodate the touch portion with a greater area, thereby effectively enhancing the touch performance of the display panel.

### BRIEF DESCRIPTION OF THE DRAWINGS

In order to more clearly illustrate the technical solutions of the embodiments of the present application, the drawings required for the embodiments of the present application will be briefly introduced below. Obviously, the drawings described below merely show some embodiments of the present application, and for those skilled in the art, other drawings may be obtained based on these drawings without inventive effort.

FIG. 1 shows a local schematic structural diagram of a display panel according to an embodiment of the present application;

FIG. 2 shows a local sectional view of a display panel according to an embodiment of the present application;

FIG. 3 shows a local schematic structural diagram of a pixel defining layer, a light-emitting device, and a touch electrode according to an embodiment of the present application;

FIG. 4 shows a local schematic structural diagram of a pixel defining layer, a light-emitting device, and a touch electrode according to another embodiment of the present application;

FIG. 5 shows a local schematic structural diagram of a pixel defining layer, a light-emitting device, and a touch electrode according to yet another embodiment of the present application;

FIG. 6 shows a local schematic structural diagram of a pixel defining layer, a light-emitting device, and a touch electrode according to yet another embodiment of the present application;

FIG. 7 shows a local schematic structural diagram of a pixel defining layer, a light-emitting device, and a touch electrode according to yet another embodiment of the present application;

FIG. 8 shows a local schematic structural diagram of a pixel defining layer, a light-emitting device, and a touch electrode according to yet another embodiment of the present application;

FIG. 9 shows a local schematic structural diagram of a pixel defining layer, a light-emitting device, and a touch electrode according to yet another embodiment of the present application;

FIG. 10 shows a local schematic structural diagram of a pixel defining layer, a light-emitting device, and a touch electrode according to yet another embodiment of the present application;

FIG. 11 shows a local schematic structural diagram of a pixel defining layer, a light-emitting device, and a touch electrode according to yet another embodiment of the present application;

FIG. 12 shows a local schematic structural diagram of a pixel defining layer, a light-emitting device, and a touch electrode according to yet another embodiment of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements comprises/includes not only those elements, but also other elements that are not explicitly listed or elements inherent to such a process, method, article or device. Without more constraints, the elements following an expression “comprise/include...” do not exclude the existence of additional identical elements in the process, method, article or device that includes the elements.

It should be understood that when describing the structure of a component, if a layer or area is referred to as being “above” or “on” another layer or area, it may mean that the layer or area is directly above/on the other layer or area, or further layer or area may be between the layer or area and the other layer or area. Furthermore, if the component is flipped, this layer or area would be “under” or “below” the other layer or area.

The embodiments of the present application provide a display panel and a display apparatus, which will be described below with reference to the accompanying drawings.

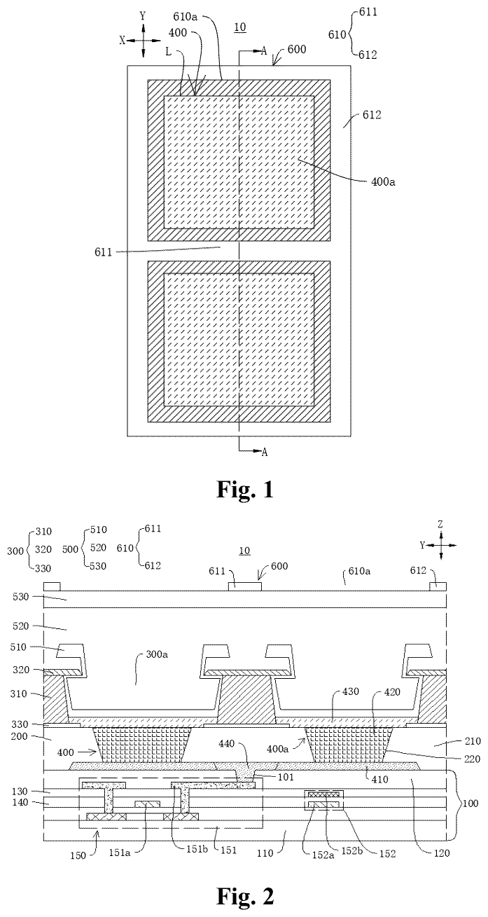

FIG. 1 shows a local schematic structural diagram of a display panel 10 according to an embodiment of the present application, and FIG. 2 shows a local sectional view of a display panel 10 according to an embodiment of the present application. Exemplarily, FIG. 2 may be a schematic sectional view along A-A in FIG. 1. In the figures, the direction X is a first direction, the direction Y is a second direction, and the direction Z may be the thickness direction of the display panel 10. Optionally, the first direction X may intersect the second direction Y, and for example, the first direction X may be perpendicular to the second direction Y. Furthermore, any two of the first direction X, the second direction Y, and the thickness direction Z of the display panel 10 may intersect, and for example, any two of the first direction X, the second direction Y, and the thickness direction Z of the display panel 10 may be perpendicular. Exemplarily, FIG. 1 may be a local schematic structural diagram of the display panel 10 without the encapsulation layer 500.

As shown in FIGS. 1 and 2, the embodiments of the first aspect of the present application provide a display panel 10, including: a base plate 100; a light-emitting device 400 arranged at one side of the base plate 100 and including a first electrode 410, a light-emitting layer 420 arranged at a side of the first electrode 410 away from the base plate 100, and a second electrode 430 arranged at a side of the light-emitting layer 420 away from the base plate 100; and a touch electrode 600 located at a side of the light-emitting device 400 away from the base plate 100 and including a touch portion 610, in which at least one light-emitting device 400 includes at least two sub-devices 400a, the first electrodes 410 of the sub-devices 400a within the light-emitting device 400 are electrically interconnected, and at least a portion of the orthographic projection of the touch portion 610 on the base plate 100 is located between the orthographic projections of the light-emitting areas L of adjacent two sub-devices 400a in a same light-emitting device 400 on the base plate 100.

The display panel 10 according to the embodiments of the present application includes the base plate 100, the light-emitting device 400, and the touch electrode 600.

Optionally, the base plate 100 may be arranged in various ways. For example, the base plate 100 may include a substrate 110, a first insulating layer 120 arranged at a side of the substrate 110 towards the light-emitting device 400, and a circuit structure 150 arranged between the substrate 110 and the first insulating layer 120.

Exemplarily, the circuit structure 150 may include a transistor 151, a storage capacitor 152, drive signal lines for connecting various devices, and the like. The transistor 151 includes a semiconductor, a gate 151a, and a source/drain 151b. The storage capacitor 152 includes a first electrode plate 152a and a second electrode plate 152b.

Optionally, the base plate 100 may further include a second insulating layer 130 arranged at one side of the substrate 110 and a third insulating layer 140 located at a side of the second insulating layer 130 towards the substrate 110, and the first insulating layer 120 may be located at a side of the second insulating layer 130 away from the substrate 110. As an example, the gate 151a and the first electrode plate 152a may be located at a side of the third insulating layer 140 towards the substrate 110, the second electrode plate 152b may be located between the third insulating layer 140 and the second insulating layer 130, and the source/drain 151b may be located between the second insulating layer 130 and the first insulating layer 120. Optionally, the first insulating layer 120 may be configured as a planarization layer in the display panel 10.

The light-emitting device 400 is arranged at one side of the base plate 100 and includes the first electrode 410, the light-emitting layer 420 arranged at the side of the first electrode 410 away from the base plate 100, and the second electrode 430 arranged at the side of the light-emitting layer 420 away from the base plate 100. The light-emitting device 400 may have a light-emitting area L, and the light-emitting device 400 within the light-emitting area L may emit light and display.

Optionally, the light-emitting area L may be the area in the light-emitting device 400 which emits light when the display panel 10 is operating. Exemplarily, the light-emitting area L may be the contact region between the first electrode 410 and the light-emitting layer 420.

Optionally, the light-emitting layer 420 may include a hole inject layer (HIL), a hole transport layer (HTL), a light-emitting structure, an electron inject layer (EIL), and an electron transport layer (ETL).

Optionally, one of the first electrode 410 and the second electrode 430 may be used as the anode and the other may be used as the cathode, so as to drive the light-emitting layer 420 to emit light. In the embodiments of the present application, for example, the first electrode 410 is the anode of the display panel 10, and the second electrode 430 is the cathode of the display panel 10.

Optionally, the first insulating layer 120 may include a through hole 101, through which the first electrode 410 may be electrically connected with the circuit structure 150 in the base pate 100. For example, the first electrode 410 may be electrically connected with the transistor 151 through the through hole 101, so that the transistor 151 can supply a drive current to the first electrode 410.

In some optional embodiments, the display panel 10 further includes a pixel defining layer 200 arranged at a side of the first electrode 410 away from the base plate 100 and may be configured to divide the light-emitting area L in the display panel 10.

Exemplarily, the pixel defining layer 200 includes a pixel defining portion 210 and a pixel opening 220 formed by the pixel defining portion 210, the light-emitting layer 420 is at least partially located within the pixel opening 220, and at least a portion of the first electrode 410 is exposed from the pixel opening 220, so that the first electrode 410 can be exposed from the pixel opening 220 to contact the light-emitting layer 420.

Optionally, the light-emitting area L may be an area corresponding to the pixel opening 220.

In some optional embodiments, the display panel 10 further includes an isolation structure 300 arranged at one side of the base plate 100 and forming an isolation opening 300a communicated with the pixel opening 220. The isolation structure 300 may be configured to separate the material between adjacent light-emitting devices 400 to facilitate the preparation of the light-emitting devices 400.

Optionally, the isolation structure 300 includes a first isolation portion 310 and a second isolation portion 320 located at a side of the first isolation portion 310 away from the base plate 100, and the second isolation portion 320 protrudes from the first isolation portion 310 towards the isolation opening 300a.

The second isolation portion 320 protrudes from the first isolation portion 310 towards the isolation opening 300a, so that when the light-emitting layer 420 and the second electrode 430 of the display panel 10 are vapor deposited, the second isolation portion 320 can shield at least a portion of the material used to prepare the light-emitting layer 420 and the second electrode 430, so as to separate the light-emitting layers 420 and the second electrodes 430 of adjacent light-emitting devices 400 and facilitate forming a plurality of light-emitting layers 420 spaced apart and a plurality of second electrodes 430 spaced apart. In this way, no fine mask is needed during the vapor deposition of the light-emitting layer 420 and the second electrode 430 of the display panel 10, and for example, no fine metal mask (FMM) is needed during the vapor deposition of the light-emitting layer 420 and the second electrode 430, thereby effectively reducing the manufacturing costs of the display panel 10.

Optionally, the isolation structure 300 may include conductive material, and the second electrode 430 may be connected with the isolation structure 300. For example, the first isolation portion 310 may include conductive material, and the second electrodes 430 of adjacent light-emitting devices 400 may be electrically connected through the isolation structure 300. That is, the second electrodes 430 of adjacent light-emitting devices 400 may be interconnected through the isolation structure 300 to form a surface electrode, facilitating control of the second electrodes 430 in the display panel 10.

Optionally, the isolation structure 300 further includes a conductive portion 330 arranged at the side of the first isolation portion 310 towards the base plate 100 and protruding from the first isolation portion 310 towards the isolation opening 300a, and the second electrode 430 is connected with the conductive portion 330. The conductive portion 330 protrudes from the first isolation portion 310 towards the isolation opening 300a to facilitate the overlapping between the second electrode 430 and the conductive portion 330, which effectively increases the overlapping area between the second electrode 430 and the conductive portion 330 and reduces the resistance of the display panel 10.

Optionally, the orthographic projection of at least one through hole 101 on the substrate 110 is located within the orthographic projection of the isolation structure 300 on the substrate 110, so that the through hole 101 can be located under the isolation structure 300 without being located at the side of the isolation structure 300 towards the isolation opening 300a, and thus the edge portion the isolation structure 300 towards the isolation opening 300a is less likely to be recessed due to the arrangement of the through hole 101, and the second electrode 430 is less likely to be affected by the arrangement of the through hole 101. In this way, the second electrode 430 can be connected smoothly with the edge of the isolation structure 300 towards the isolation opening 300a, thereby effectively enhancing the connection reliability between the second electrode 430 and the isolation structure 300.

Optionally, the relative position between the pixel defining portion 210 and the isolation structure 300 may be arranged in various ways. For example, the isolation structure 300 may be arranged at the side of the pixel defining portion 210 away from the base plate 100, i.e., the isolation structure 300 may be arranged directly on the pixel defining portion 210. Alternatively, the pixel defining portion 210 may include an accommodating groove (not shown), and at least a portion of the isolation structure 300 may be located within the groove, so that the isolation structure 300 is less likely to have an excessively great height relative to the base plate 100, thereby effectively reducing the thickness of the display panel 10. For ease of description, in the following embodiments, for example, the isolation structure 300 is arranged at the side of the pixel defining portion 210 away from the base plate 100.

At least one light-emitting device 400 may include at least two sub-devices 400a, and the first electrodes 410 of the sub-devices 400a within the light-emitting device 400 may be electrically interconnected, thereby facilitating controlling the light emission of the sub-devices 400a within the light-emitting device 400.

Optionally, each sub-device 400a may include a light-emitting area L, and the light-emitting areas L of adjacent two sub-devices 400a may be spaced apart. Exemplarily, each sub-device 400a may include one light-emitting area L, and thus if a single light-emitting device 400 includes at least two sub-devices 400a, the light-emitting device 400 may further include the same number of light-emitting areas L as the number of the sub-devices 400a. For example, if a single light-emitting device 400 includes two sub-devices 400a, the light-emitting device 400 may include two light-emitting areas L.

Optionally, the sub-devices 400a within a same light-emitting device 400 emit lights of a same color.

Optionally, the circuit structure 150 may include a plurality of drive circuits. The first electrodes 410 of the sub-devices 400a within a same light-emitting device 400 may be electrically connected with a same drive circuit, and for example, the first electrodes 410 of the sub-devices 400a within a same light-emitting device 400 may be electrically connected with a same transistor 151 in a same drive circuit. The first electrodes 410 of different light-emitting devices 400 may be electrically connected with different drive circuits, and for example, the first electrodes 410 of different light-emitting devices 400 may be electrically connected with the transistors 151 of different drive circuits.

Optionally, a portion of the orthographic projection of the pixel defining portion 210 on the base plate 100 is located between the orthographic projections of the light-emitting areas L of adjacent two sub-devices 400a in a same light-emitting device 400 on the base plate 100, so that the pixel defining portion 210 may be configured to divide the light-emitting areas L of adjacent two sub-devices 400a in a same light-emitting device 400.

Optionally, the light-emitting areas L of different sub-devices 400a may correspond to different pixel openings 220, and thus if a single light-emitting device 400 includes at least two sub-devices 400a, the light-emitting device 400 may be arranged corresponding to at least two pixel openings 220, i.e., the orthographic projections of at least two pixel openings 220 on the base plate 100 may be located within the orthographic projection of a same light-emitting device 400 on the base plate 100.

Optionally, the orthographic projection of the pixel opening 220 on the base plate 100 may refer to the orthographic projection of the inner wall of the pixel opening 220 on the base plate 100, as well as the projection area formed by the orthographic projection of the inner wall of the pixel opening 220 on the base plate 100.

Optionally, a portion of the orthographic projection of the isolation structure 300 on the base plate 100 is located between the orthographic projections of the light-emitting areas L of adjacent two sub-devices 400a in a same light-emitting device 400 on the base plate 100, so that the isolation structure 300 may also be configured to separate the material between adjacent sub-devices 400a to facilitate the preparation of the sub-devices 400a.

Exemplarily, the isolation structure 300 may be configured to separate the light-emitting layers 420 and the second electrodes 430 of adjacent sub-devices 400a, i.e., the light-emitting layers 420 and the second electrodes 430 of different sub-devices 400a may be located within different isolation openings 300a.

Optionally, the first electrodes 410 of the sub-devices 400a within a same light-emitting device 400 may be electrically connected directly or indirectly.

Optionally, the first electrodes 410 of the sub-devices 400a within a same light-emitting device 400 may be connected with the circuit structure 150 in the base plate 100 through a same through hole 101, thereby effectively reducing the number of the though holes 101 in the display panel 10 and facilitating the arrangement of the various devices in the base plate 100.

By dividing at least one light-emitting device 400 into at least two sub-devices 400a, when some sub-devices 400a in the light-emitting device 400 exhibit poor light emission, some other sub-devices 400a in the light-emitting device 400 can still achieve satisfactory light emission and display, so that the light-emitting device 400 as a whole can continue to emit light, thereby effectively enhancing the operational reliability of the light-emitting device 400.

The touch electrode 600 is located at the side of the light-emitting device 400 away from the base plate 100 and may be configured to achieve the touch function of the display panel 10.

Optionally, the touch electrode 600 may be arranged at the side of the isolation structure 300 away from the base plate 100.

In some optional embodiments, the display panel 10 further includes an encapsulation layer 500 arranged at the side of the isolation structure 300 and the light-emitting device 400 away from the base plate 100. The encapsulation layer 500 may be configured to achieve the encapsulation of the display panel 10.

Exemplarily, the touch electrode 600 may be located at the side of the encapsulation layer 500 away from the base plate 100.

Optionally, the encapsulation layer 500 may include a first encapsulation layer 510 arranged at the side of the isolation structure 300 and the light-emitting device 400 away from the base plate 100. Optionally, the first encapsulation layer 510 may include inorganic material, so that the first encapsulation layer 510 can effectively reduce the impact of moisture on the operation of the light-emitting device 400. Exemplarily, the first encapsulation layer 510 may be prepared using chemical vapor deposition (CVD) process.

Optionally, the first encapsulation layer 510 may include a plurality of encapsulation units, in which different encapsulation units may be configured to encapsulate different light-emitting devices 400 relatively independently. Exemplarily, adjacent encapsulation units may be spaced apart to facilitate relatively independent encapsulation of different light-emitting devices 400 by different encapsulation units.

Optionally, different encapsulation units may also be configured to encapsulate different sub-devices 400a relatively independently. The encapsulation units corresponding to adjacent two sub-devices 400a may also be spaced apart, so that when some sub-devices 400a in the light-emitting device 400 exhibit poor light emission due to poor encapsulation, some other sub-devices 400a in the light-emitting device 400 can still have good encapsulation results and achieve good light emission and display.

Optionally, the encapsulation layer 500 further includes a second encapsulation layer 520 located at the side of the first encapsulation layer 510 away from the base plate 100, thereby effectively enhancing the encapsulation effect for the display panel 10. Optionally, the second encapsulation layer 520 may include organic material, so that during the preparation process of the display panel 10, the second encapsulation layer 520 can exhibit good flowability, and thus the surface of the second encapsulation layer 520 away from the base plate 100 can have good flatness, facilitating the formation of subsequent film layers. Exemplarily, the second encapsulation layer 520 may be prepared using inkjet printing (IJP) technology.

Optionally, the encapsulation layer 500 may further include a third encapsulation layer 530 located at the side of the second encapsulation layer 520 away from the base plate 100, thereby effectively enhancing the encapsulation effect for the display panel 10. Optionally, the third encapsulation layer 530 may include inorganic material, so that the third encapsulation layer 530 can effectively reduce the impact of moisture on the operation of the light-emitting device 400. Exemplarily, the third encapsulation layer 530 may be prepared using chemical vapor deposition process.

The touch electrode 600 includes the touch portion 610, and at least a portion of the orthographic projection of the touch portion 610 on the base plate 100 is located between the orthographic projections of the light-emitting areas L of adjacent two sub-devices 400a in a same light-emitting device 400 on the base plate 100, so that the touch portion 610 can extend over the gap between the light-emitting areas L of adjacent two sub-devices 400a in a same light-emitting device 400. In this way, the touch portion 610 is less likely to block the light emission and display of the light-emitting device 400, and the space within the display panel 10 can be effectively utilized to accommodate the touch portion 610 with a greater area, thereby effectively enhancing the touch performance of the display panel 10.

Optionally, the orthographic projection of the touch portion 610 on the base plate 100 may be located within the orthographic projection of the pixel defining portion 210 on the base plate 100, so that the touch electrode 600 is less likely to block the light emission of the light-emitting device 400, thereby effectively enhancing the display performance of the display panel 10.

Optionally, a minimum spacing between an edge of the orthographic projection of the touch portion 610 on the base plate 100 and an edge of the orthographic projection of the pixel defining portion 210 on the base plate 100 is greater than or equal to 2 μm, so that the touch portion 610 and the pixel opening 220 can be suitably spaced apart, thereby effectively reducing the blocking of the touch electrode 600 on the light emitted by the light-emitting device 400.

Optionally, the orthographic projection of the touch portion 610 on the base plate 100 is located within the orthographic projection of the isolation structure 300 on the base plate 100, so that the touch electrode 600 is less likely to block the light emitted by the light-emitting device 400 through the isolation opening 300a, thereby effectively enhancing the display performance of the display panel 10.

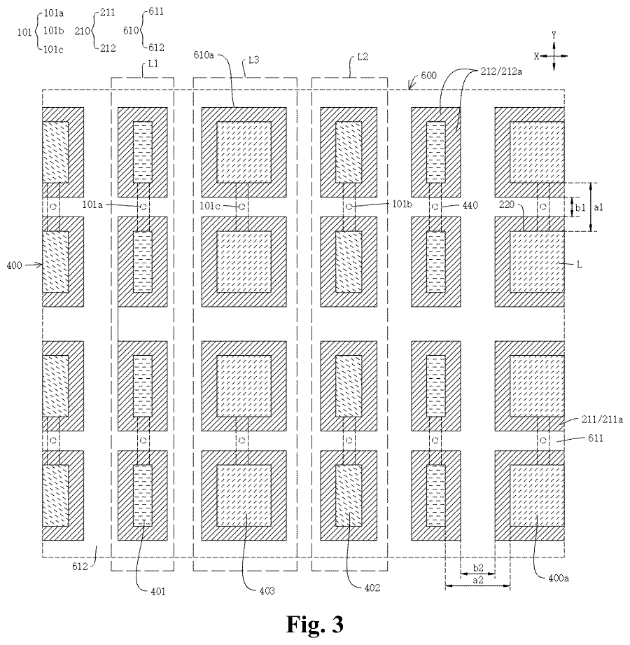

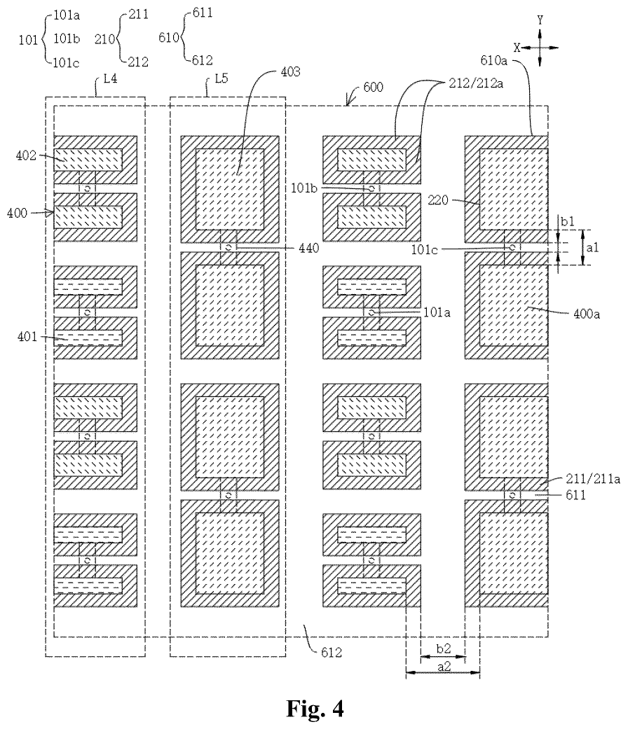

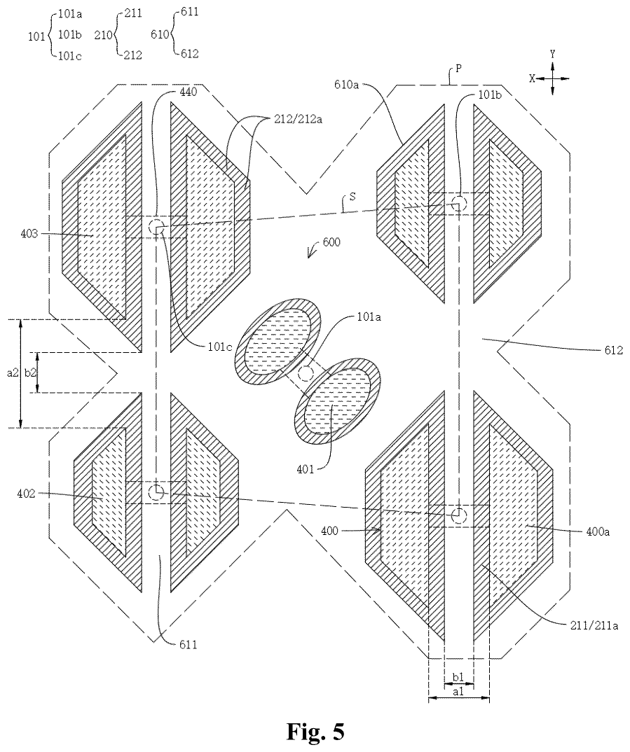

FIG. 3 shows a local schematic structural diagram of a pixel defining layer 200, a light-emitting device 400, and a touch electrode 600 according to an embodiment of the present application, FIG. 4 shows a local schematic structural diagram of a pixel defining layer 200, a light-emitting device 400, and a touch electrode 600 according to another embodiment of the present application, and FIG. 5 shows a local schematic structural diagram of a pixel defining layer 200, a light-emitting device 400, and a touch electrode 600 according to yet another embodiment of the present application.

In some optional embodiments, the light-emitting device 400 includes a first light-emitting device 401, a second light-emitting device 402, and a third light-emitting device 403 emitting lights of different colors, so as to achieve color display of the display panel 10.

Exemplary, the first light-emitting device 401 emits green light, the second light-emitting device 402 emits red light, and the third light-emitting device 403 emits blue light.

Optionally, the through hole 101 includes a first via 101a, a second via 101b, and a third via 101c. The first electrode 410 in the first light-emitting device 401 is electrically connected with the transistor 151 through the first via 101a, the first electrode 410 in the second light-emitting device 402 is electrically connected with the transistor 151 through the second via 101b, and the first electrode 410 in the third light-emitting device 403 is electrically connected with the transistor 151 through the third via 101c.

Optionally, the area of the light-emitting area L of the third light-emitting device 403 is greater than or equal to the area of the light-emitting area L of the second light-emitting device 402, and the area of the light-emitting area L of the second light-emitting device 402 is greater than or equal to the area of the light-emitting area L of the first light-emitting device 401.

Optionally, the area of the light-emitting area L of the first light-emitting device 401 may refer to the area of the orthographic projection of the light-emitting area L of the first light-emitting device 401 on the base plate 100. Optionally, the area of the light-emitting area L of the second light-emitting device 402 may refer to the area of the orthographic projection of the light-emitting area L of the second light-emitting device 402 on the base plate 100. Optionally, the area of the light-emitting area L of the third light-emitting device 403 may refer to the area of the orthographic projection of the light-emitting area L of the third light-emitting device 403 on the base plate 100.

For ease of description, in the following embodiments, for example, the area of the light-emitting area L of the third light-emitting device 403 is greater than the area of the light-emitting area L of the second light-emitting device 402, and the area of the light-emitting area L of the second light-emitting device 402 is greater than the area of the light-emitting area L of the first light-emitting device 401.

In some embodiments of the present application, the touch portion 610 may include a plurality of touch segments. One touch segment may be arranged correspondingly above and between adjacent sub-devices 400a, and one touch segment may also be arranged correspondingly above and between adjacent light-emitting devices 400.

As shown in FIGS. 3 to 5, in some optional embodiments, the touch portion 610 includes a first touch segment 611 and a second touch segment 612, the orthographic projection of the first touch segment 611 on the base plate 100 is located between the orthographic projections of the light-emitting areas L of adjacent two sub-devices 400a in a same light-emitting device 400 on the base plate 100, and the orthographic projection of the second touch segment 612 on the base plate 100 is located between the orthographic projections of the light-emitting areas L of adjacent two light-emitting devices 400 on the base plate 100.

Optionally, the first touch segment 611 and the second touch segment 612 may be interconnected. For example, the first touch segment 611 and the second touch segment 612 may be integrally formed.

Optionally, the orthographic projection of the touch portion 610 on the base plate 100 is arranged at least partially surrounding the orthographic projection of light-emitting area L of the light-emitting device 400 on the base plate 100, and the orthographic projection of the touch portion 610 on the base plate 100 is arranged at least partially surrounding the orthographic projections of the light-emitting areas L of the sub-devices 400a on the base plate 100; and the touch portion 610 forms a touch opening 610a, and the orthographic projection of light-emitting area L of at least one of the sub-devices 400a on the base plate 100 is located within the orthographic projection of the touch opening 610a on the base plate 100.

Optionally, the touch opening 610a may be formed by both the first touch segment 611 and the second touch segment 612.

In these optional embodiments, with the first touch segment 611 and the second touch segment 612, the touch portion 610 can extend over the gap between the light-emitting areas L of adjacent two sub-devices 400a in a same light-emitting device 400, and the touch portion 610 can also extend above the gap between the light-emitting areas L of adjacent light-emitting devices 400, so that the space within the display panel 10 can be further utilized to accommodate the touch portion 610 with a greater area, thereby effectively enhancing the touch performance of the display panel 10.

In some embodiments of the present application, the pixel defining portion 210 may include a plurality of defining segments. One defining segment may be arranged correspondingly between adjacent sub-devices 400a, and one defining segment may also be arranged correspondingly between adjacent light-emitting devices 400.

In some optional embodiments, the pixel defining portion 210 may include a first defining portion 211 and a second defining portion 212, the orthographic projection of the first defining portion 211 on the base plate 100 is located between the orthographic projections of the light-emitting areas L of adjacent two sub-devices 400a in a same light-emitting device 400 on the base plate 100, and the orthographic projection of the second defining portion 212 on the base plate 100 is located between the orthographic projections of the light-emitting areas L of adjacent two light-emitting devices 400 on the base plate 100; the first defining portion 211 includes a first defining segment 211a, and the orthographic projection of the first defining segment 211a on the base plate 100 overlaps the orthographic projection of the first touch segment 611 on the base plate 100; the second defining portion 212 includes a second defining segment 212a, and the orthographic projection of the second defining segment 212a on the base plate 100 overlaps the orthographic projection of the second touch segment 612 on the base plate 100.

Optionally, the first defining portion 211 and the second defining portion 212 may be interconnected. For example, the first defining portion 211 and the second defining portion 212 may be integrally formed.

Optionally, the orthographic projection of the first touch segment 611 on the base plate 100 may be located within the orthographic projection of the first defining segment 211a on the base plate 100.

Optionally, the orthographic projection of the second touch segment 612 on the base plate 100 may be located within the orthographic projection of the second defining segment 212a on the base plate 100.

In these optional embodiments, the first defining portion 211 may be configured to divide the light-emitting areas L of adjacent two sub-devices 400a in a same light-emitting device 400, and the second defining portion 212 may be configured to divide the light-emitting areas L of adjacent light-emitting devices 400. The orthographic projection of the first defining segment 211a on the base plate 100 overlaps the orthographic projection of the first touch segment 611 on the base plate 100, and the orthographic projection of the second defining segment 212a on the base plate 100 overlaps the orthographic projection of the second touch segment 612 on the base plate 100, so that the first touch segment 611 is less likely to block the light emission and display of the adjacent sub-devices 400a and the second touch segment 612 is less likely to block the light emission and display of the adjacent light-emitting devices 400, thereby effectively enhancing the display performance of the display panel 10.

In some optional embodiments, the width of the orthographic projection of the first defining segment 211 a on the base plate 100 is greater than or equal to 8 μm, and the width of the orthographic projection of the second defining segment 212a on the base plate 100 is greater than or equal to 8 μm.

Optionally, the width of the orthographic projection of the first defining segment 211a on the base plate 100 may refer to the dimension of the orthographic projection of the first defining segment 211a on the base plate 100 along the arrangement direction of the adjacent two pixel openings 220 located respectively at two sides of the first defining segment 211a.

Optionally, the dimension of the orthographic projection of the first defining segment 211a on the base plate 100 may refer to the minimum spacing between opposite two edges of the orthographic projection of the first defining segment 211a on the base plate 100. For example, a1 as shown may indicate the width of the orthographic projection of the first defining segment 211a on the base plate 100.

Optionally, the width of the orthographic projection of the second defining segment 212a on the base plate 100 may refer to the dimension of the orthographic projection of the second defining segment 212a on the base plate 100 along the arrangement direction of the adjacent two pixel openings 220 located respectively at two sides of the second defining segment 212a.

Optionally, the dimension of the orthographic projection of the second defining segment 212a on the base plate 100 may refer to the minimum spacing between opposite two edges of the orthographic projection of the second defining segment 212a on the base plate 100. For example, a2 as shown may indicate the width of the orthographic projection of the second defining segment 212a on the base plate 100.

In these optional embodiments, the wider first and second defining segments 211a and 212a facilitate arranging the wider first and second touch segments 611 and 612 respectively above the first and second defining segments 211a and 212a, thereby facilitating the preparation of the touch portion 610 and effectively enhancing the touch performance of the touch electrode 600.

Exemplarily, the width of the orthographic projection of the first touch segment 611 on the base plate 100 may be greater than or equal to 4 μm, and the width of the orthographic projection of the second touch segment 612 on the base plate 100 may also be greater than or equal to 4 μm, so that the first touch segment 611 and the second touch segment 612 can have a favorable width.

Optionally, the width of the orthographic projection of the first touch segment 611 on the base plate 100 may refer to the minimum spacing between opposite two edges of the orthographic projection of the first touch segment 611 on the base plate 100. For example, b1 as shown may indicate the width of the orthographic projection of the first touch segment 611 on the base plate 100.

Optionally, the width of the orthographic projection of the second touch segment 612 on the base plate 100 may refer to the minimum spacing between opposite two edges of the orthographic projection of the second touch segment 612 on the base plate 100. For example, b2 as shown may indicate the width of the orthographic projection of the second touch segment 612 on the base plate 100.

In some optional embodiments, the width of the orthographic projection of the second defining segment 212a on the base plate 100 may be greater than the width of the orthographic projection of the first defining segment 211a on the base plate 100, so that the light-emitting areas L of adjacent light-emitting devices 400 can have a greater spacing, thereby facilitating the preparation of the light-emitting layers 420 and the second electrodes 430 of the light-emitting devices 400 emitting lights of different colors using the isolation structure 300.

Exemplarily, in preparing the light-emitting devices 400 emitting lights of different colors using the isolation structure 300, the width of the orthographic projection of the second defining segment 212a on the base plate 100 is greater than the width of the orthographic projection of the first defining segment 211a on the base plate 100, and thus the light-emitting areas L of adjacent light-emitting devices 400 can have a greater spacing, so that when etching, using etching material, the material of the light-emitting layer 420 and the second electrode 430, which are redundant, within a portion of the isolation openings 300a, the etching material is less likely to invade the material of the light-emitting layer 420 and the second electrode 430, which should be retained, within another portion of the isolation openings 300a, thereby reducing difficulty of the preparation process the display panel 10.

Optionally, the width of the orthographic projection of the second touch segment 612 on the base plate 100 is greater than the width of the orthographic projection of the first touch segment 611 on the base plate 100. Under a condition that the width of the orthographic projection of the second defining segment 212a on the base plate 100 is greater than the width of the orthographic projection of the first defining segment 211a on the base plate 100, the width of the orthographic projection of the second touch segment 612 on the base plate 100 is greater than the width of the orthographic projection of the first touch segment 611 on the base plate 100, so that the spacing between the light-emitting areas L of adjacent light-emitting devices 400 can be effectively utilized to arrange a wider second touch segment 612, thereby effectively enhancing the touch performance of the display panel 10 and preventing the touch portion 610 from affecting the light emission of the display panel 10.

In some optional embodiments, the orthographic projection of at least one through hole 101 on the substrate 110 is located within the orthographic projection of the first defining portion 211 and/or the second defining portion 212 on the substrate 110.

Optionally, the orthographic projection of at least one through hole 101 on the substrate 110 is located within the orthographic projection of the touch portion 610 on the substrate 110.

Exemplarily, the orthographic projection of at least one through hole 101 on the substrate 110 is located within the orthographic projection of the first touch segment 611 on the substrate 110, and/or the orthographic projection of at least one through hole 101 on the substrate 110 is located within the orthographic projection of the second touch segment 612 on the substrate 110.

In these optional embodiments, with at least one through hole 101 be arranged under the wider first defining portion 211 and/or second defining portion 212, the through hole 101 is less likely to affect the flatness of the light-emitting device 400 within the light-emitting area L, thereby effectively enhancing the display performance of the display panel 10. Moreover, if the through hole 101 is arranged under the first defining portion 211, e.g., if the orthographic projection of the through hole 101 on the substrate 110 is located within the orthographic projection of the first touch segment 611 on the substrate 110, the through-hole 101 can be suitably located between the light-emitting areas L of adjacent two sub-devices 400a in the light-emitting device 400, which facilitates the first electrodes 410 of adjacent two sub-devices 400a in the light-emitting device 400 being connected with the transistor 151 in the base plate 100 through a same through hole 101.

In some optional embodiments, the display panel 10 further includes a connection structure 440 arranged in the same layer as the first electrode 410, the connection structure 440 may be located between the first electrodes 410 of the at least two sub-devices 400a in a same light-emitting device 400, and the first electrodes 410 of the at least two sub-devices 400a in a same light-emitting device 400 may be electrically connected through the connection structure 440.

Optionally, the connection structure 440 may be partially located within the through hole 101, so that the first electrode 410 can be electrically connected with the transistor 151 in the base plate 100 through the connection structure 440 and the through hole 101. Exemplarily, if the orthographic projection of at least one through hole 101 on the substrate 110 is located within the orthographic projection of the first defining portion 211 on the substrate 110, i.e., when if the through hole 101 is arranged under the first defining portion 211, the connection structure 440 may be partially located within the through hole 101 under the first defining portion 211.

Optionally, the connection structure 440 and the first electrodes 410 of a portion of the sub-devices 400a may be integrally formed.

Optionally, the orthographic projection of the touch portion 610 on the base plate 100 partially overlaps the orthographic projection of the connection structure 440 on the base plate 100.

In these optional embodiments, the connection structure 440 may be configured to achieve the electrical connection between the first electrodes 410 of adjacent sub-devices 400a. During the preparation and inspection of the display panel 10, if some sub-devices 400a of the light-emitting device 400 in the display panel 10 exhibit poor light emission (e.g., caused by short circuits) due to impurities (e.g., dust, processing material debris, or other contaminants), the connection structure 440 surrounding the sub-device 400a with poor light emission may be cut (e.g., using laser cutting) to disconnect the electrical connection between the first electrode 410 of the sub-device 400a with poor light emission and the first electrodes 410 of other sub-devices 400a which are not affected by impurities. For example, the electrical connection between the first electrode 410 of the sub-device 400a with poor light emission and the connection structure 440 within the through hole 101 may be disconnected, so that other sub-devices 400a which are not affected by impurities can still achieve good light emission through the connection structure 440, thereby improving the production yield of the display panel 10.

Optionally, the orthographic projection of the connection structure 440 on be base plate 100 may be strip-shaped, thereby facilitating the cutting of the connection structure 440 surrounding the sub-device 400a with poor light emission.

Optionally, during the preparation and inspection of the display panel 10, the connection structure 440 surrounding the sub-device 400a with poor light emission may be cut to disconnect the electrical connection between the first electrode 410 of the sub-device 400a with poor light emission and the first electrodes 410 of other sub-devices 400a which are not affected by impurities. Therefore, after the connection structure 440 surrounding some sub-devices 400a being cut during the preparation and inspection of the display panel 10, in the display panel 10 formed after the preparation and inspection, the first electrodes 410 of at least two sub-devices 400a in at least one light-emitting device 400 may not be electrically connected through the connection structure 440.

In some optional embodiments, the light-emitting areas L corresponding to a plurality of sub-devices 400a in a same light-emitting device 400 are of equal areas.

In some optional embodiments, the orthographic projections of the light-emitting areas L of the sub-devices 400a in a same light-emitting device 400 on the base plate 100 may be distributed axially symmetrically about the orthographic projection of a central axis of the first defining segment 211a on the base plate 100.

The central axis of the first defining segment 211a may refer to the central axis of the first defining segment 211a extending along a direction perpendicular to the width direction of the first defining segment 211a, and the distance from this central axis to the edge of the first defining segment 211a towards the pixel opening 220 located at any side of the first defining segment 211a remains the same.

Optionally, the orthographic projections of the light-emitting areas L of at least two sub-devices 400a in a same light-emitting device 400 on the substrate 110 are distributed centrally symmetrically about a centroid of the orthographic projection of the through hole 101 on the substrate 110.

In these optional embodiments, the orthographic projections of the light-emitting areas L of the sub-devices 400a in a same light-emitting device 400 on the base plate 100 may be distributed axially symmetrically about the orthographic projection of the central axis of the first defining segment 211a on the base plate 100, or the orthographic projections of the light-emitting areas L of at least two sub-devices 400a in a same light-emitting device 400 on the substrate 110 are distributed centrally symmetrically about the centroid of the orthographic projection of the through hole 101 on the substrate 110, so that if the orthographic projection of at least one through hole 101 on the substrate 110 is located within the orthographic projection of the first defining portion 211 on the substrate 110, the distance between the through hole 101 located under the first defining portion 211 and the first electrodes 410 of various sub-devices 400a can be relatively less, thereby facilitating, during the preparation and inspection of the display panel 10, disconnecting the electrical connection between the first electrode 410 of the sub-device 400a with poor light emission and the first electrodes 410 of other sub-devices 400a which are not affected by impurities.

In some optional embodiments, as shown in FIGS. 3 to 5, the orthographic projection of the touch portion 610 on the base plate 100 may be arranged surrounding the orthographic projection of the light-emitting area L of the sub-device 400a on the base plate 100, and the orthographic projection of the touch portion 610 on the base plate 100 may be arranged surrounding the orthographic projection of the light-emitting area L of the light-emitting device 400 on the base plate 100, so that the touch electrode 600 with a greater area may be arranged in the display panel 10, thereby effectively enhancing the touch capability of the display panel 10.

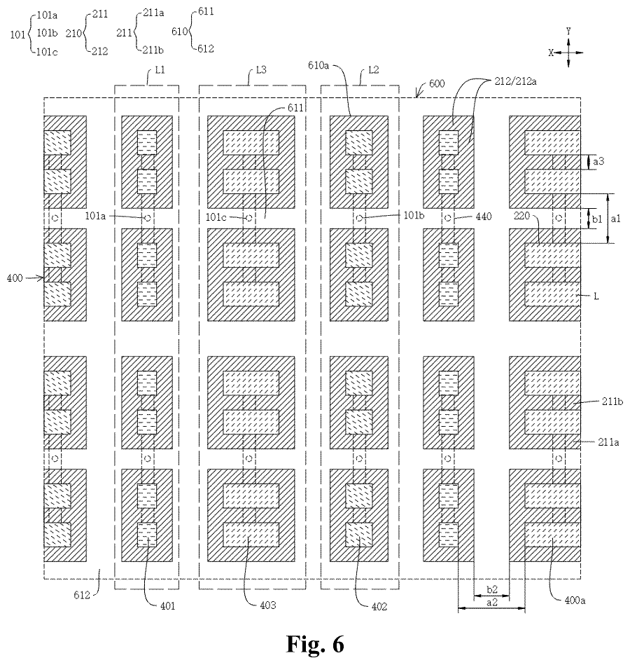

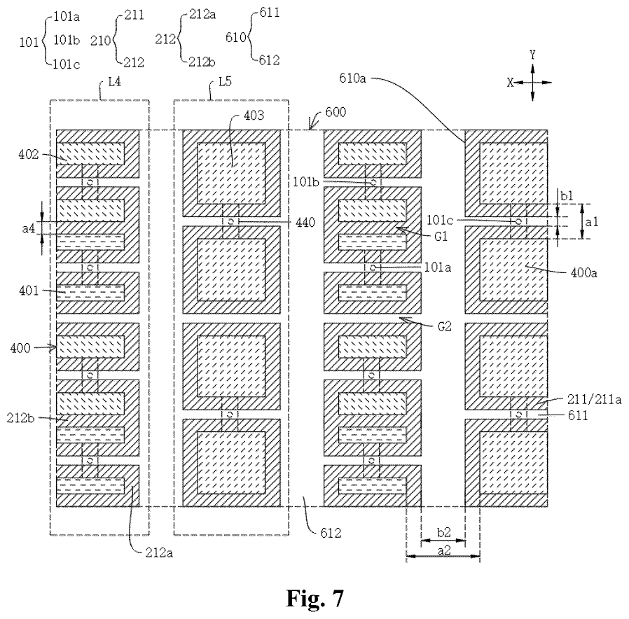

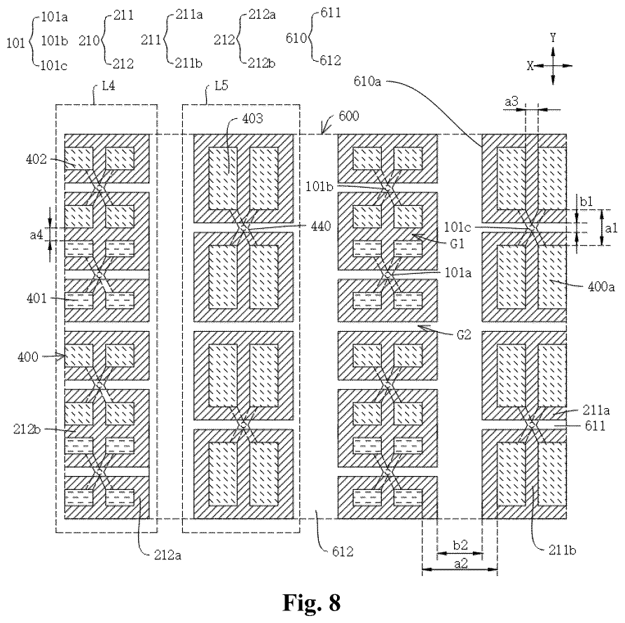

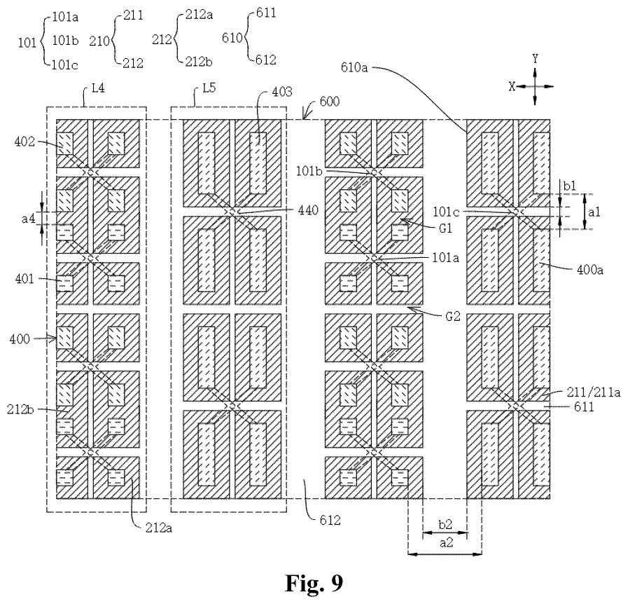

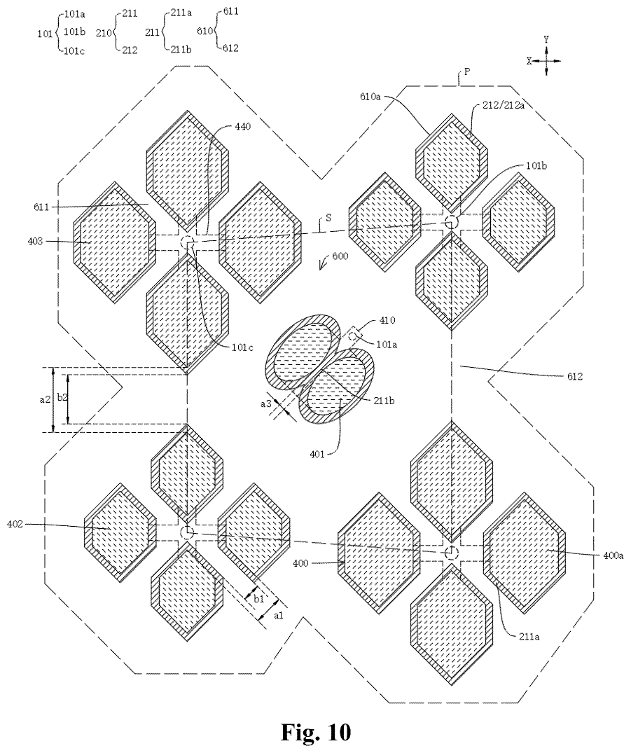

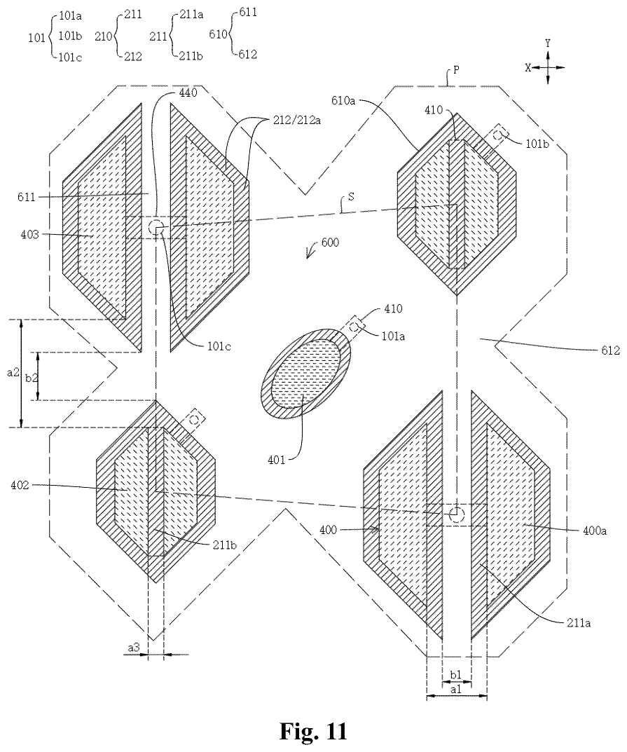

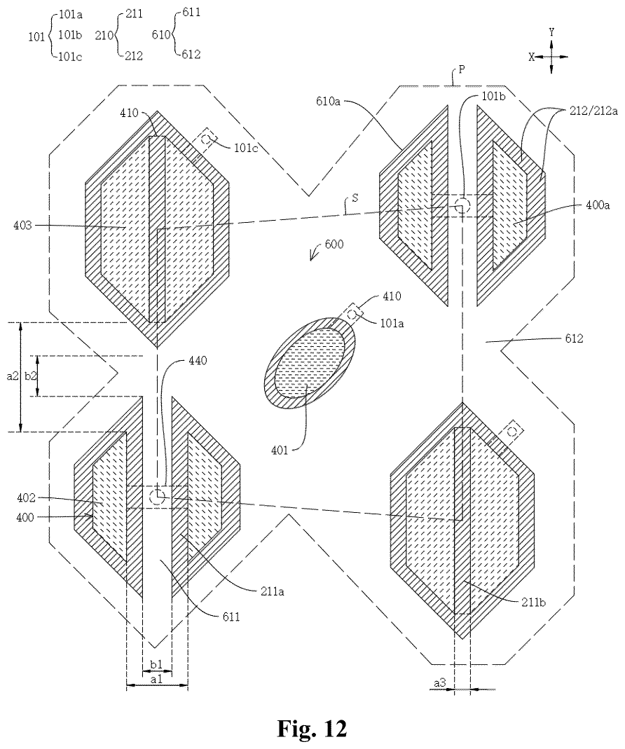

FIG. 6 shows a local schematic structural diagram of a pixel defining layer 200, a light-emitting device 400, and a touch electrode 600 according to yet another embodiment of the present application, FIG. 7 shows a local schematic structural diagram of a pixel defining layer 200, a light-emitting device 400, and a touch electrode 600 according to yet another embodiment of the present application, FIG. 8 shows a local schematic structural diagram of a pixel defining layer 200, a light-emitting device 400, and a touch electrode 600 according to yet another embodiment of the present application, FIG. 9 shows a local schematic structural diagram of a pixel defining layer 200, a light-emitting device 400, and a touch electrode 600 according to yet another embodiment of the present application, FIG. 10 shows a local schematic structural diagram of a pixel defining layer 200, a light-emitting device 400, and a touch electrode 600 according to yet another embodiment of the present application, FIG. 11 shows a local schematic structural diagram of a pixel defining layer 200, a light-emitting device 400, and a touch electrode 600 according to yet another embodiment of the present application, and FIG. 12 shows a local schematic structural diagram of a pixel defining layer 200, a light-emitting device 400, and a touch electrode 600 according to yet another embodiment of the present application.

In some optional embodiments, as shown in FIGS. 6, 8, 10, 11, and 12, no touch portion 610 is arranged between the light-emitting areas L of at least some adjacent sub-devices 400a in a same light-emitting device 400, so that the light-emitting areas L of some adjacent sub-devices 400a in a same light-emitting device 400 can have a smaller spacing, which facilitates increasing the pixel density of the display panel 10 and the aperture ratio of pixels of the display panel 10, and that the touch electrode 600 is less likely to have an excessively great layout area, which facilitates the touch control module driving the touch portion 610, and thus the touch control module does not require substantial drive capability to drive a touch portion 610 with an excessively great area.

Exemplarily, in a same light-emitting device 400, no touch portion 610 is arranged between the light-emitting areas L of some adjacent sub-devices 400a, and the touch portion 610 may be arranged between the light-emitting areas L of some other adjacent sub-devices 400a.

Optionally, the first defining portion 211 further includes a third defining segment 211b, the orthographic projection of the third defining segment 211b on the base plate 100 does not overlap the orthographic projection of the touch portion 610 on the base plate 100, and the width of the orthographic projection of the first defining segment 211a on the base plate 100 and the width of the orthographic projection of the second defining segment 212a on the base plate 100 are both greater than the width of the orthographic projection of the third defining segment 211b on the base plate 100.

Exemplarily, in a same light-emitting device 400, no third defining segment 211b is arranged between the light-emitting areas L of some adjacent sub-devices 400a, and the third defining segment 211b may be arranged between the light-emitting areas L of some other adjacent sub-devices 400a.

Optionally, as shown in FIG. 6, no touch portion 610 is arranged between the light-emitting areas L of the sub-devices 400a adjacent in the second direction Y in a same light-emitting device 400, and the orthographic projection of the third defining segment 211b on the base plate 100 may be located between the orthographic projections of the light-emitting areas L of the sub-devices 400a adjacent in the second direction Y on the base plate 100.

Optionally, as shown in FIG. 8, no touch portion 610 is arranged between the light-emitting areas L of the sub-devices 400a adjacent in the first direction X in a same light-emitting device 400, and the orthographic projection of the third defining segment 211b on the base plate 100 may be located between the orthographic projections of the light-emitting areas L of the sub-devices 400a adjacent in the first direction X on the base plate 100.

The width of the orthographic projection of the first defining segment 211a on the base plate 100 and the width of the orthographic projection of the second defining segment 212a on the base plate 100 are both greater than the width of the orthographic projection of the third defining segment 211b on the base plate 100, so that the third defining segment 211b can have a smaller width, and the light-emitting areas L of some adjacent sub-devices 400a in a same light-emitting device 400 can have a smaller spacing, which facilitates increasing the pixel density of the display panel 10 and the aperture ratio of pixels of the display panel 10.

Optionally, the width of the orthographic projection of the third defining segment 211b on the base plate 100 may refer to the minimum spacing between opposite two edges of the orthographic projection of the third defining segment 211b on the base plate 100. For example, a3 as shown may indicate the width of the orthographic projection of the third defining segment 211b on the base plate 100.

Exemplarily, the width of the orthographic projection of the third defining segment 211b on the base plate 100 is less than 8 μm.

In some optional embodiments, as shown in FIGS. 7 to 9, no touch portion 610 is arranged between the light-emitting areas L of adjacent light-emitting devices 400, so that the light-emitting areas L of adjacent light-emitting devices 400 can have a smaller spacing, which facilitates increasing the pixel density of the display panel 10 and the aperture ratio of pixels of the display panel 10, and that the touch portion 610 is less likely to have an excessively great layout area, which facilitates the touch control module driving the touch portion 610, and thus the touch control module does not require substantial drive capability to drive a touch portion 610 with an excessively great area.

Optionally, as shown in FIG. 8, the second defining portion 212 further includes a fourth defining segment 212b, the orthographic projection of the fourth defining segment 212b on the base plate 100 does not overlap the orthographic projection of the touch portion 610 on the base plate 100, and the width of the orthographic projection of the first defining segment 211a on the base plate 100 and the width of the orthographic projection of the second defining segment 212a on the base plate 100 are both greater than the width of the orthographic projection of the fourth defining segment 212b on the base plate 100.

The width of the orthographic projection of the first defining segment 211a on the base plate 100 and the width of the orthographic projection of the second defining segment 212a on the base plate 100 are both greater than the width of the orthographic projection of the fourth defining segment 212b on the base plate 100, so that the fourth defining segment 212b can have a smaller width, and the light-emitting areas L of adjacent light-emitting devices 400 can have a smaller spacing, which facilitates increasing the pixel density of the display panel 10 and the aperture ratio of pixels of the display panel 10.

Optionally, the width of the orthographic projection of the fourth defining segment 212b on the base plate 100 may refer to the minimum spacing between opposite two edges of the orthographic projection of the fourth defining segment 212b on the base plate 100. For example, a4 as shown may indicate the width of the orthographic projection of the fourth defining segment 212b on the base plate 100.

Exemplarily, the width of the orthographic projection of the fourth defining segment 212b on the base plate 100 is less than 8 μm.

In some embodiments of the present application, the width of the isolation structure 300 may be set according to the width of the pixel defining portion 210. For example, the width of the orthographic projection of the isolation structure 300 located above the second defining segment 212a on base plate 100 may be greater than the width of the orthographic projection of the isolation structure 300 located above the first defining segment 211a on base plate 100. For example, the width of the orthographic projection of the isolation structure 300 located above the first defining segment 211a and the second defining segment 212a on base plate 100 may be greater than the width of the orthographic projection of the isolation structure 300 located above the third defining segment 211b on base plate 100. For example, the width of the orthographic projection of the isolation structure 300 located above the first defining segment 211a and the second defining segment 212a on base plate 100 may be greater than the width of the orthographic projection of the isolation structure 300 located above the fourth defining segment 212b on base plate 100.

In some optional embodiments, at least one of the first light-emitting device 401, the second light-emitting device 402, and the third light-emitting device 403 includes at least two sub-devices 400a.

Herein, if a light-emitting device 400 does not include two or more sub-devices 400a, it may be considered that this light-emitting device 400 includes only one sub-device 400a.

Optionally, at least one of the first light-emitting device 401, the second light-emitting device 402, and the third light-emitting device 403 may include only one sub-device 400a, which is not limited herein.

In some optional embodiments, as shown in FIGS. 3 to 9, the number of sub-devices 400a in the first light-emitting device 401, the number of sub-devices 400a in the second light-emitting device 402, and the number of sub-devices 400a in the third light-emitting device 403 are all equal. For example, the number of sub-devices 400a in the first light-emitting device 401, the number of sub-devices 400a in the second light-emitting device 402, and the number of sub-devices 400a in the third light-emitting device 403 are all equal and two or more, so that the light-emitting devices 400 can achieve good operational reliability, thereby enhancing the overall operational reliability of the display panel 10.

In some other optional embodiments, as shown in FIGS. 10 to 12, the number of sub-devices 400a in the first light-emitting device 401 is less than the number of sub-devices 400a in the third light-emitting device 403.

Optionally, the number of sub-devices 400a in the first light-emitting device 401 may also be less than the number of sub-devices 400a in the second light-emitting device 402.

In this optional embodiment, since the light-emitting area L of the first light-emitting device 401 has a small area, the number of sub-devices 400a in the first light-emitting device 401 is less, so that the light-emitting area L of each sub-device 400a in the first light-emitting device 401 is less likely to have an excessively small area, and the first light-emitting device 401 can achieve good light-emitting effect, thereby effectively enhancing the display effect of the display panel 10. Furthermore, in this way, the second electrode 430 of each sub-device 400a in the first light-emitting device 401 may have a greater contact area with the isolation structure 300, which effectively reduces the resistance and enhances the operational stability of the display panel 10. Additionally, for the light-emitting device 400 having the light-emitting area L with a greater area, the probability of dark spot defects is also higher, the number of sub-devices 400a is greater, and thus the probability of all sub-devices 400a in a same light-emitting device 400 suffering dark spot defects can be reduced.

In some embodiments of the present application, the number of sub-devices 400a in the light-emitting device 400 and the position of the touch portion 610 may be set according to the color of light and the area of the light-emitting area L of the light-emitting device 400.

In some optional embodiments, as shown in FIGS. 3 to 11, the third light-emitting device 403 includes at least two sub-devices 400a, and at least a portion of the orthographic projection of the first touch segment 611 on the base plate 100 is located between the orthographic projections of the light-emitting areas L of adjacent two sub-devices 400a in the third light-emitting device 403 on the base plate 100.

Optionally, at least a portion of the orthographic projection of the first defining segment 211a on the base plate 100 may be located between the orthographic projections of the light-emitting areas L of adjacent two sub-devices 400a in the third light-emitting device 403 on the base plate 100.

Optionally, the orthographic projection of the third via 101c on the substrate 110 is located between the orthographic projections of the light-emitting areas L of adjacent two sub-devices 400a in the third light-emitting device 403 on the substrate 110.

Exemplarily, the orthographic projection of the third via 101c on the substrate 110 may be located within the orthographic projection of the first defining segment 211a on the substrate 110.

Optionally, if the orthographic projection of the third via 101c on the substrate 110 may be located within the orthographic projection of the first defining segment 211a on the substrate 110, the connection structure 440 may be located between the first electrodes 410 of the sub-devices 400a in the third light-emitting device 403, the connection structure 440 may be partially located within the third via 101c, and the first electrodes 410 of the sub-devices 400a in the third light-emitting device 403 may be electrically connected through the connection structure 440.

In these optional embodiments, since the light-emitting area of the third light-emitting device 403 is large, the third light-emitting device 403 includes at least two sub-devices 400a, so that the light-emitting area L of each sub-device 400a in the third light-emitting device 403 is less likely to have an excessively small area, the third light-emitting device 403 can achieve good light-emitting effect, and the second electrode 430 of each sub-device 400a in the third light-emitting device 403 can have a greater contact area with the isolation structure 300, thereby enhancing the operational performance of the display panel 10. Furthermore, the light-emitting area of the third light-emitting device 403 is large, so that the light-emitting areas L of adjacent sub-devices 400a in the third light-emitting device 403 can have a greater spacing, and thus the wider first defining segment 211a, touch portion 610, and third via 101c can be arranged at the corresponding positions between the light-emitting areas L of adjacent sub-devices 400a in the third light-emitting device 403. Moreover, for the light-emitting device having the light-emitting area L with a greater area, the probability of dark spot defects is also higher, with the orthographic projection of the third via 101c on the substrate 110 being located between the orthographic projections of the light-emitting areas L of adjacent two sub-devices 400a in the third light-emitting device 403 on the substrate 110, and the connection structure 440 being located between the first electrodes 410 of the sub-devices 400a in the third light-emitting device 403, if some sub-devices 400a in the third light-emitting device 403 suffer dark spot defects, the connection structure 440 surrounding the sub-devices 400a with dark spot defects in the third light-emitting device 403 may be cut, so that other sub-devices 400a which are not affected by impurities can still achieve good light emission through the connection structure 440, thereby improving the production yield of the display panel 10.

In some optional embodiments, as shown in FIGS. 3 to 9, the first light-emitting device 401 and the second light-emitting device 402 each include at least two sub-devices 400a, a portion of the orthographic projection of the first touch segment 611 on the base plate 100 is located between the orthographic projections of the light-emitting areas L of adjacent two sub-devices 400a in the first light-emitting device 401 on the base plate 100, and a portion of the orthographic projection of the first touch segment 611 on the base plate 100 is located between the orthographic projections of the light-emitting areas L of adjacent two sub-devices 400a in the second light-emitting device 402 on the base plate 100.

Optionally, the first light-emitting device 401, the second light-emitting device 402, and the third light-emitting device 403 each include at least two sub-devices 400a, a portion of the orthographic projection of the first touch segment 611 on the base plate 100 is located between the orthographic projections of the light-emitting areas L of adjacent two sub-devices 400a in the first light-emitting device 401 on the base plate 100, a portion of the orthographic projection of the first touch segment 611 on the base plate 100 is located between the orthographic projections of the light-emitting areas L of adjacent two sub-devices 400a in the second light-emitting device 402 on the base plate 100, and a portion of the orthographic projection of the first touch segment 611 on the base plate 100 is located between the orthographic projections of the light-emitting areas L of adjacent two sub-devices 400a in the third light-emitting device 403 on the base plate 100.

Optionally, a portion of the orthographic projection of the first defining segment 211a on the base plate 100 may be located between the orthographic projections of the light-emitting areas L of adjacent two sub-devices 400a in the first light-emitting device 401 on the base plate 100, and a portion of the orthographic projection of the first defining segment 211a on the base plate 100 may be located between the orthographic projections of the light-emitting areas L of adjacent two sub-devices 400a in the second light-emitting device 402 on the base plate 100.

Optionally, the orthographic projection of the first via 101a on the substrate 110 is located between the orthographic projections of the light-emitting areas L of adjacent two sub-devices 400a in the first light-emitting device 401 on the substrate 110, and/or the orthographic projection of the second via 101b on the substrate 110 is located between the orthographic projections of the light-emitting areas L of adjacent two sub-devices 400a in the second light-emitting device 402 on the substrate 110.

Exemplarily, the orthographic projections of the first via 101a and the second via 101b on the substrate 110 may be both located within the orthographic projection of the first defining segment 211a on the substrate 110.

Optionally, if the orthographic projection of the first via 101a on the substrate 110 is located between the orthographic projections of the light-emitting areas L of adjacent two sub-devices 400a in the first light-emitting device 401 on the substrate 110, the connection structure 440 may be located between the first electrodes 410 of the sub-devices 400a in the first light-emitting device 401, the connection structure 440 may be partially located within the first via 101a, and the first electrodes 410 of the sub-devices 400a in the first light-emitting device 401 may be electrically connected through the connection structure 440.

Optionally, if the orthographic projection of the second via 101b on the substrate 110 is located between the orthographic projections of the light-emitting areas L of adjacent two sub-devices 400a in the second light-emitting device 402 on the substrate 110, the connection structure 440 may be located between the first electrodes 410 of the sub-devices 400a in the second light-emitting device 402, the connection structure 440 may be partially located within the second via 101b, and the first electrodes 410 of the sub-devices 400a in the second light-emitting device 402 may be electrically connected through the connection structure 440.

In these optional embodiments, the number of sub-devices 400a in the first light-emitting device 401, the number of sub-devices 400a in the second light-emitting device 402, and the number of sub-devices 400a in the third light-emitting device 403 are each two or more, so that each light-emitting device 400 can achieve good operational reliability, thereby enhancing the overall operational reliability of the display panel 10. The touch portion 610 may be arranged correspondingly above and between the light-emitting areas L of adjacent two sub-devices 400a in the first light-emitting device 401, above and between the light-emitting areas L of adjacent two sub-devices 400a in the second light-emitting device 402, and above and between the light-emitting areas L of adjacent two sub-devices 400a in the third light-emitting device 403, so that the layout area of the touch electrode 600 can be effectively increased, thereby effectively enhancing the touch capability of the display panel 10. Furthermore, the through hole 101 may be arranged correspondingly below and between the light-emitting areas L of adjacent two sub-devices 400a in the first light-emitting device 401, below and between the light-emitting areas L of adjacent two sub-devices 400a in the second light-emitting device 402, and below and between the light-emitting areas L of adjacent two sub-devices 400a in the third light-emitting device 403, which facilitates the connection between the connection structure 440 and the first electrodes 410 of the sub-devices 400a in the light-emitting device 400, and the through hole 101 can be suitably located at the center of the light-emitting device 400, which facilitates cutting the connection structure 440 surrounding the sub-device 400a with poor light emission during the preparation and inspection of the display panel 10.

In some optional embodiments, at least a portion of the orthographic projection of the second touch segment 612 on the base plate 100 is located between the orthographic projections of the light-emitting areas L of the first light-emitting device 401 and the third light-emitting device 403 that are adjacent on the base plate 100, and/or at least a portion of the orthographic projection of the second touch segment 612 on the base plate 100 is located between the orthographic projections of the light-emitting areas L of the second light-emitting device 402 and the third light-emitting device 403 that are adjacent on the base plate 100.

Optionally, a portion of the orthographic projection of the second defining segment 212a on the base plate 100 may be located between the orthographic projections of the light-emitting areas L of the first light-emitting device 401 and the third light-emitting device 403 that are adjacent on the base plate 100, and/or a portion of the orthographic projection of the second defining segment 212a on the base plate 100 may be located between the orthographic projections of the light-emitting areas L of the second light-emitting device 402 and the third light-emitting device 403 that are adjacent on the base plate 100.

In these optional embodiments, the touch portion 610 may be arranged correspondingly above and between the orthographic projections of the light-emitting areas L of the first light-emitting device 401 and the third light-emitting device 403 that are adjacent on the base plate 100 and above and between the orthographic projections of the light-emitting areas L of the second light-emitting device 402 and the third light-emitting device 403 that are adjacent on the base plate 100, which facilitates effectively increasing the layout area of the touch electrode 600 and enhancing the touch capability of the display panel 10.

In some optional embodiments, as shown in FIGS. 7 to 9, if a portion of the orthographic projection of the first touch segment 611 on the base plate 100 is located between the orthographic projections of the light-emitting areas L of adjacent two sub-devices 400a in the first light-emitting device 401 on the base plate 100, a portion of the orthographic projection of the first touch segment 611 on the base plate 100 is located between the orthographic projections of the light-emitting areas L of adjacent two sub-devices 400a in the second light-emitting device 402 on the base plate 100, and a portion of the orthographic projection of the first touch segment 611 on the base plate 100 is located between the orthographic projections of the light-emitting areas L of adjacent two sub-devices 400a in the third light-emitting device 403 on the base plate 100, a first gap G1 is between light-emitting areas L of the first light-emitting device 401 and the second light-emitting device 402 that are adjacent, and at least a portion of the orthographic projection of the first gap G1 on the base plate 100 may not overlap the orthographic projection of the second touch segment 612 on the base plate 100. Optionally, the orthographic projection of the first gap G1 on the base plate 100 may refer to the projection area between the orthographic projections of the opposite edges of the light-emitting areas L of the first light-emitting device 401 and the second light-emitting device 402 on the base plate 100.

Exemplarily, at least a portion of the orthographic projection of the fourth defining segment 212b on the base plate 100 may be located between the orthographic projections of the light-emitting areas L of the first light-emitting device 401 and the second light-emitting device 402 that are adjacent on the base plate 100.

In these optional embodiments, the touch portion 610 is arranged correspondingly above and between the light-emitting areas L of adjacent two sub-devices 400a in the first light-emitting device 401, above and between the light-emitting areas L of adjacent two sub-devices 400a in the second light-emitting device 402, and above and between the light-emitting areas L of adjacent two sub-devices 400a in the third light-emitting device 403, so that the touch electrode 600 can have a sufficient layout area to achieve the touch function of the display panel 10. Therefore, no touch portion 610 is arranged above and between the light-emitting areas L of the first light-emitting device 401 and the second light-emitting device 402, which have a smaller area, to adjust the layout area of the touch electrode 600, so that the layout area of the touch electrode 600 is less likely to be excessively great, which facilitates the touch control module driving the touch portion 610, and thus the touch control module does not require substantial drive capability to drive a touch portion 610 with an excessively great area. Furthermore, in this way, the first light-emitting device 401 and the second light-emitting device 402, which have the light-emitting areas L with a small area, can have a smaller spacing, thereby facilitating increasing the pixel density of the display panel 10.

Optionally, as shown in FIGS. 7 to 9, a second gap G2 may be further between the light-emitting areas L of the first light-emitting device 401 and the second light-emitting device 402 that are adjacent, and at least a portion of the orthographic projection of the second touch segment 612 on the base plate 100 may overlap the orthographic projection of the second gap G2 on the base plate 100, thereby effectively adjusting the layout area of the touch electrode 600.

Optionally, the orthographic projection of the second gap G2 on the base plate 100 may refer to the projection area between the orthographic projections of the opposite edges of the light-emitting areas L of the first light-emitting device 401 and the second light-emitting device 402 on the base plate 100.

In some optional embodiments, as shown in FIG. 10, the first light-emitting device 401 includes at least two sub-devices 400a, and the orthographic projection of the first touch segment 611 on the base plate 100 is not located between the orthographic projections of the light-emitting areas L of adjacent two sub-devices 400a in the first light-emitting device 401 on the base plate 100.

Optionally, a portion of the orthographic projection of the first defining segment 211a on the base plate 100 may be located between the orthographic projections of the light-emitting areas L of adjacent two sub-devices 400a in the second light-emitting device 402 on the base plate 100.

Optionally, the orthographic projection of the first via 101a on the substrate 110 is not located between the orthographic projections of the light-emitting areas L of adjacent two sub-devices 400a in the first light-emitting device 401 on the base plate 100.

Exemplarily, the orthographic projection of at least one first via 101a on the substrate 110 is located between the orthographic projections of the light-emitting areas L of the first light-emitting device 401 and the second light-emitting device 402 that are adjacent on the base plate 100, and/or the orthographic projection of at least one first via 101a on the substrate 110 is located between the orthographic projections of the light-emitting areas L of the first light-emitting device 401 and the third light-emitting device 403 that are adjacent on the base plate 100.

Exemplarily, the orthographic projection of the first via 101a on the substrate 110 may be located within the orthographic projection of the second defining segment 212a on the substrate 110, and the orthographic projection of the second via 101b on the substrate 110 may be located within the orthographic projection of the first defining segment 211a on the substrate 110.

Optionally, if the orthographic projection of the first via 101a on the substrate 110 is not located between the orthographic projections of the light-emitting areas L of adjacent two sub-devices 400a in the first light-emitting device 401 on the substrate 110, the first electrodes 410 of the sub-devices 400a in the first light-emitting device 401 may be directly interconnected to form a block-shaped first electrode 410.

In these optional embodiments, the orthographic projection of the first touch segment 611 on the base plate 100 may be not located between the orthographic projections of the light-emitting areas L of adjacent two sub-devices 400a in the first light-emitting device 401 on the base plate 100, so that the layout area of the touch electrode 600 is less likely to be excessively great, which facilitates the touch control module driving the touch portion 610. Furthermore, since the light-emitting area L of the first light-emitting device 401 has a small area, adjacent sub-devices 400a in the first light-emitting device 401 can have a smaller spacing, which increases the aperture ratio of the first light-emitting device 401, so that the first light-emitting device 401 as a whole can achieve good light-emitting effect.

In some optional embodiments, as shown in FIG. 10, the first light-emitting device 401 and the second light-emitting device 402 each include at least two sub-devices 400a, the orthographic projection of the first touch segment 611 on the base plate 100 may be not located between the orthographic projections of the light-emitting areas L of adjacent two sub-devices 400a in the first light-emitting device 401 on the base plate 100, and a portion of the orthographic projection of the first touch segment 611 on the base plate 100 is located between the orthographic projections of the light-emitting areas L of adjacent two sub-devices 400a in the second light-emitting device 402 on the base plate 100.

Optionally, the first light-emitting device 401, the second light-emitting device 402, and the third light-emitting device 403 each include at least two sub-devices 400a, the orthographic projection of the first touch segment 611 on the base plate 100 may be not located between the orthographic projections of the light-emitting areas L of adjacent two sub-devices 400a in the first light-emitting device 401 on the base plate 100, a portion of the orthographic projection of the first touch segment 611 on the base plate 100 is located between the orthographic projections of the light-emitting areas L of adjacent two sub-devices 400a in the second light-emitting device 402 on the base plate 100, and a portion of the orthographic projection of the first touch segment 611 on the base plate 100 is located between the orthographic projections of the light-emitting areas L of adjacent two sub-devices 400a in the third light-emitting device 403 on the base plate 100.

Optionally, at least a portion of the orthographic projection of the second touch segment 612 on the base plate 100 is located between the orthographic projections of the light-emitting areas L of the first light-emitting device 401 and the second light-emitting device 402 that are adjacent on the base plate 100, and/or at least a portion of the orthographic projection of the second touch segment 612 on the base plate 100 is located between the orthographic projections of the light-emitting areas L of the first light-emitting device 401 and the third light-emitting device 403 that are adjacent on the base plate 100, and/or at least a portion of the orthographic projection of the second touch segment 612 on the base plate 100 is located between the orthographic projections of the light-emitting areas L of the second light-emitting device 402 and the third light-emitting device 403 that are adjacent on the base plate 100.

Exemplarily, a portion of the orthographic projection of the second defining segment 212a on the base plate 100 may be located between the orthographic projections of the light-emitting areas L of the first light-emitting device 401 and the second light-emitting device 402 that are adjacent on the base plate 100, and/or a portion of the orthographic projection of the second defining segment 212a on the base plate 100 may be located between the orthographic projections of the light-emitting areas L of the first light-emitting device 401 and the third light-emitting device 403 that are adjacent on the base plate 100, and/or a portion of the orthographic projection of the second defining segment 212a on the base plate 100 may be located between the orthographic projections of the light-emitting areas L of the second light-emitting device 402 and the third light-emitting device 403 that are adjacent on the base plate 100.

Optionally, a portion of the orthographic projection of the third defining segment 211b on base plate 100 may be located between the orthographic projections of the light-emitting areas L of adjacent two sub-devices 400a in the first light-emitting device 401 on the base plate 100, and a portion of the orthographic projection of the first defining segment 211a on base plate 100 may be located between the orthographic projections of the light-emitting areas L of adjacent two sub-devices 400a in the second light-emitting device 402 on the base plate 100.

Optionally, the orthographic projection of the first via 101a on the substrate 110 is not located between the orthographic projections of the light-emitting areas L of adjacent two sub-devices 400a in the first light-emitting device 401 on the substrate 110, and/or the orthographic projection of the second via 101b on the substrate 110 is located between the orthographic projections of the light-emitting areas l of adjacent two sub-devices 400a in the second light-emitting device 402 on the substrate 110.

In these optional embodiments, since a portion of the orthographic projection of the first touch segment 611 on the base plate 100 is located between the orthographic projections of the light-emitting areas L of adjacent two sub-devices 400a in the second light-emitting device 402 on the base plate 100, the touch electrode 600 can have a suitable layout area to achieve the touch function of the display panel 10. Therefore, the orthographic projection of the first touch segment 611 on the base plate 100 may be not located between the orthographic projections of the light-emitting areas L of adjacent two sub-devices 400a in the first light-emitting device 401 on the base plate 100, so that the layout area of the touch electrode 600 is less likely to be excessively great, which facilitates the touch control module driving the touch portion 610. Furthermore, since the light-emitting area L of the first light-emitting device 401 has a small area, adjacent sub-devices 400a in the first light-emitting device 401 can have a smaller spacing, so that the first light-emitting device 401 as a whole can achieve good light-emitting effect.

In some optional embodiments, as shown in FIG. 11, the second light-emitting device 402 includes at least two sub-devices 400a, and the orthographic projection of the first touch segment 611 on the base plate 100 is not located between the orthographic projections of the light-emitting areas L of adjacent two sub-devices 400a in the second light-emitting device 402 on the base plate 100.

Optionally, the first light-emitting device 401 and the second light-emitting device 402 each include at least two sub-devices 400a, the orthographic projection of the first touch segment 611 on the base plate 100 is not located between the orthographic projections of the light-emitting areas L of adjacent two sub-devices 400a in the second light-emitting device 402 on the base plate 100, and at least a portion of the orthographic projection of the first touch segment 611 on the base plate 100 is located between the orthographic projections of the light-emitting areas L of adjacent two sub-devices 400a in the third light-emitting device 403 on the base plate 100.

Optionally, the first light-emitting device 401 may include only one sub-device 400a.

Optionally, at least a portion of the orthographic projection of the second touch segment 612 on the base plate 100 is located between the orthographic projections of the light-emitting areas L of the first light-emitting device 401 and the second light-emitting device 402 that are adjacent on the base plate 100, and/or at least a portion of the orthographic projection of the second touch segment 612 on the base plate 100 is located between the orthographic projections of the light-emitting areas L of the first light-emitting device 401 and the third light-emitting device 403 that are adjacent on the base plate 100, and/or at least a portion of the orthographic projection of the second touch segment 612 on the base plate 100 is located between the orthographic projections of the light-emitting areas L of the second light-emitting device 402 and the third light-emitting device 403 that are adjacent on the base plate 100.

Exemplarily, a portion of the orthographic projection of the second defining segment 212a on the base plate 100 may be located between the orthographic projections of the light-emitting areas L of the first light-emitting device 401 and the second light-emitting device 402 that are adjacent on the base plate 100, and/or a portion of the orthographic projection of the second defining segment 212a on the base plate 100 may be located between the orthographic projections of the light-emitting areas L of the first light-emitting device 401 and the third light-emitting device 403 that are adjacent on the base plate 100, and/or a portion of the orthographic projection of the second defining segment 212a on the base plate 100 may be located between the orthographic projections of the light-emitting areas L of the second light-emitting device 402 and the third light-emitting device 403 that are adjacent on the base plate 100.

Optionally, a portion of the orthographic projection of the third defining segment 211b on the base plate 100 may be located between the orthographic projections of the light-emitting areas L of adjacent two sub-devices 400a in the second light-emitting device 402 on the base plate 100.

Optionally, the orthographic projection of the second via 101b on the substrate 110 is not located between the orthographic projections of the light-emitting areas L of adjacent two sub-devices 400a in the second light-emitting device 402 on the base plate 100.

Exemplarily, the orthographic projection of at least one second via 101b on the substrate 110 is located between the orthographic projections of the light-emitting areas L of the first light-emitting device 401 and the second light-emitting device 402 that are adjacent on the base plate 100, and/or the orthographic projection of at least one second via 101b on the substrate 110 is located between the orthographic projections of the light-emitting areas L of the second light-emitting device 402 and the third light-emitting device 403 that are adjacent on the base plate 100.

Exemplarily, the orthographic projection of the second via 101b on the substrate 110 may be located within the orthographic projection of the second defining segment 212a on the substrate 110.

Optionally, if the orthographic projection of the second via 101b on the substrate 110 is not located between the orthographic projections of the light-emitting areas L of adjacent two sub-devices 400a in the second light-emitting device 402 on the substrate 110, the first electrodes 410 of the sub-devices 400a in the second light-emitting device 402 may be directly interconnected to form a block-shaped first electrode 410.

In these optional embodiments, the orthographic projection of the first touch segment 611 on the base plate 100 may be not located between the orthographic projections of the light-emitting areas L of adjacent two sub-devices 400a in the second light-emitting device 402 on the base plate 100, so that the layout area of the touch electrode 600 is less likely to be excessively great, which facilitates the touch control module driving the touch portion 610, and adjacent sub-devices 400a in the second light-emitting device 402 can have a smaller spacing, which increases the aperture ratio of the second light-emitting device 402, so that the second light-emitting device 402 as a whole can achieve good light-emitting effect.

In some optional embodiments, as shown in FIG. 12, the second light-emitting device 402 and the third light-emitting device 403 each include at least two sub-devices 400a, the orthographic projection of the first touch segment 611 on the base plate 100 is not located between the orthographic projections of the light-emitting areas L of adjacent two sub-devices 400a in the third light-emitting device 403 on the base plate 100, and a portion of the orthographic projection of the first touch segment 611 on the base plate 100 is located between the orthographic projections of the light-emitting areas L of adjacent two sub-devices 400a in the second light-emitting device 402 on the base plate 100.

Optionally, the first light-emitting device 401 may include only one sub-device 400a.

Optionally, at least a portion of the orthographic projection of the first defining segment 211a on the base plate 100 may be located between the orthographic projections of the light-emitting areas L of adjacent two sub-devices 400a in the second light-emitting device 402 on the base plate 100.

Optionally, the orthographic projection of the second via 101b on the substrate 110 may be located between the orthographic projections of the light-emitting areas L of adjacent two sub-devices 400a in the second light-emitting device 402 on the base plate 100.

Exemplarily, the orthographic projection of the second via 101b on the substrate 110 may be located within the orthographic projection of the first defining segment 211a on the base plate 100.

Optionally, at least a portion of the orthographic projection of the second touch segment 612 on the base plate 100 is located between the orthographic projections of the light-emitting areas L of the first light-emitting device 401 and the second light-emitting device 402 that are adjacent on the base plate 100, and/or at least a portion of the orthographic projection of the second touch segment 612 on the base plate 100 is located between the orthographic projections of the light-emitting areas L of the first light-emitting device 401 and the third light-emitting device 403 that are adjacent on the base plate 100, and/or at least a portion of the orthographic projection of the second touch segment 612 on the base plate 100 is located between the orthographic projections of the light-emitting areas L of the second light-emitting device 402 and the third light-emitting device 403 that are adjacent on the base plate 100.

Exemplarily, a portion of the orthographic projection of the second defining segment 212a on the base plate 100 may be located between the orthographic projections of the light-emitting areas L of the first light-emitting device 401 and the second light-emitting device 402 that are adjacent on the base plate 100, and/or a portion of the orthographic projection of the second defining segment 212a on the base plate 100 may be located between the orthographic projections of the light-emitting areas L of the first light-emitting device 401 and the third light-emitting device 403 that are adjacent on the base plate 100, and/or a portion of the orthographic projection of the second defining segment 212a on the base plate 100 may be located between the orthographic projections of the light-emitting areas L of the second light-emitting device 402 and the third light-emitting device 403 that are adjacent on the base plate 100.

Optionally, a portion of the orthographic projection of the third defining segment 211b on the base plate 100 may be located between the orthographic projections of the light-emitting areas L of adjacent two sub-devices 400a in the third light-emitting device 403 on the base plate 100.

Optionally, the orthographic projection of the third via 101c on the substrate 110 may be not located between the orthographic projections of the light-emitting areas L of adjacent two sub-devices 400a in the third light-emitting device 403 on the base plate 100.

Exemplarily, the orthographic projection of at least one third via 101c on the substrate 110 is located between the orthographic projections of the light-emitting areas L of the first light-emitting device 401 and the third light-emitting device 403 that are adjacent on the base plate 100, and/or the orthographic projection of at least one third via 101c on the substrate 110 is located between the orthographic projections of the light-emitting areas L of the second light-emitting device 402 and the third light-emitting device 403 that are adjacent on the base plate 100.

Exemplarily, the orthographic projection of the third via 101c on the substrate 110 may be located within the orthographic projection of the second defining segment 212a on the substrate 110.

Optionally, if the orthographic projection of the third via 101c on the substrate 110 is not located between the orthographic projections of the light-emitting areas L of adjacent two sub-devices 400a in the third light-emitting device 403 on the substrate 110, the first electrodes 410 of the sub-devices 400a in the third light-emitting device 403 may be directly interconnected to form a block-shaped first electrode 410.

In these optional embodiments, the orthographic projection of the first touch segment 611 on the base plate 100 may be not located between the orthographic projections of the light-emitting areas L of adjacent two sub-devices 400a in the third light-emitting device 403 on the base plate 100, so that the layout area of the touch electrode 600 is less likely to be excessively great, which facilitates the touch control module driving the touch portion 610, and if the third light-emitting device 403 emits blue light, adjacent sub-devices 400a in the third light-emitting device 403, which has low light-emitting efficiency, can have a smaller spacing, so that the third light-emitting device 403 as a whole can achieve good light-emitting effect.

In some embodiments of the present application, the various light-emitting devices 400 may be arranged in various ways.

In some optional embodiments, as shown in FIGS. 3 and 6, a plurality of first light-emitting devices 401 are distributed along the second direction Y in sequence to form a first pixel column L1, a plurality of second light-emitting devices 402 are distributed along the second direction Y in sequence to form a second pixel column L2, a plurality of third light-emitting devices 403 are distributed along the second direction Y in sequence to form a third pixel column L3, and the second pixel column L2, the first pixel column L1, and the third pixel column L3 are distributed alternately along the X first direction in sequence.

In some optional embodiments, as shown in FIGS. 4, 7, 8, and 9, a plurality of first light-emitting devices 401 and a plurality of second light-emitting devices 402 are distributed alternately along the second direction Y to form a fourth pixel column L4, a plurality of third light-emitting devices 403 are distributed along the second direction Y in sequence to form a fifth pixel column L5, and the fourth pixel column L4 and the fifth pixel column L5 are distributed alternately along the first direction X in sequence.

In some optional embodiments, as shown in FIGS. 5, 10, 11, and 12, one first light-emitting device 401, two second light-emitting devices 402, and two third light-emitting devices 403 form a pixel group P, the pixel groups P may be distributed in an arrayed along the first direction X and the second direction Y; in a single pixel group P, the first light-emitting device 401 is located within a virtual quadrilateral S, two opposite vertices of the virtual quadrilateral S coincide with centers of the two second light-emitting devices 402, respectively, and the other two opposite vertices of the virtual quadrilateral S coincide with centers of the two third light-emitting devices 403, respectively.

The embodiments of the second aspect of the present application provide a display apparatus including the display panel 10 of any of the above embodiments. Since the display apparatus according to the embodiments of the second aspect of the present application includes the display panel 10 of any of the embodiments of the first aspect, the display apparatus according to the embodiments of the second aspect of the present application has the beneficial effects of the display panel 10 of any of the embodiments of the first aspect, which are not repeated herein.

The display apparatus in the embodiments of the present application includes, but is not limited to, devices with display function such as mobile phones, personal digital assistants (PDA), tablet computers, e-readers, televisions, access control systems, smart landline telephones, and consoles.

The embodiments of the present application as described above do not exhaustively describe all details and do not limit the present application to the specific embodiments described herein. Obviously, numerous modifications and variations can be made based on the above description. These embodiments are selected and described in detail in the specification to better explain the principles and practical applications of the present application, thereby enabling those skilled in the art to effectively utilize the present application and made modifications based thereon. The present application is limited only by the scope of the claims and their equivalents.

What is claimed is:

1. A display panel, comprising:
a base plate;
a light-emitting device arranged at one side of the base plate and comprising a first electrode, a light-emitting layer arranged at a side of the first electrode away from the base plate, and a second electrode arranged at a side of the light-emitting layer away from the base plate; and
a touch electrode located at a side of the light-emitting device away from the base plate and comprising a touch portion,
wherein at least one light-emitting device comprises at least two sub-devices, the first electrodes of the sub-devices within the light-emitting device are electrically interconnected, and at least a portion of an orthographic projection of the touch portion on the base plate is located between orthographic projections of light-emitting areas of adjacent two sub-devices in a same light-emitting device on the base plate.

2. The display panel of claim 1, wherein the touch portion comprises a first touch segment and a second touch segment, an orthographic projection of the first touch segment on the base plate is located between orthographic projections of light-emitting areas of adjacent two sub-devices in a same light-emitting device on the base plate, and an orthographic projection of the second touch segment on the base plate is located between orthographic projections of light-emitting areas of adjacent two light-emitting devices on the base plate.

3. The display panel of claim 2, wherein the orthographic projection of the touch portion on the base plate is arranged at least partially surrounding an orthographic projection of a light-emitting area of the light-emitting device on the base plate, and the orthographic projection of the touch portion on the base plate is arranged at least partially surrounding orthographic projections of light-emitting areas of the sub-devices on the base plate; and
the touch portion forms a touch opening, and an orthographic projection of light-emitting area of at least one of the sub-devices on the base plate is located within an orthographic projection of the touch opening on the base plate.

4. The display panel of claim 2, wherein the display panel further comprises a pixel defining layer arranged at a side of the first electrode away from the base plate and comprising a pixel defining portion and a pixel opening formed by the pixel defining portion, the light-emitting layer is at least partially located within the pixel opening, at least a portion of the first electrode is exposed from the pixel opening, and a portion of an orthographic projection of the pixel defining portion on the base plate is located between orthographic projections of light-emitting areas of adjacent two sub-devices in a same light-emitting device on the base plate.

5. The display panel of claim 4, wherein the orthographic projection of the touch portion on the base plate is located within the orthographic projection of the pixel defining portion on the base plate; and
a minimum spacing between an edge of the orthographic projection of the touch portion on the base plate and an edge of the orthographic projection of the pixel defining portion on the base plate is greater than or equal to 2 μm.

6. The display panel of claim 4, wherein the pixel defining portion comprises a first defining portion and a second defining portion, an orthographic projection of the first defining portion on the base plate is located between orthographic projections of light-emitting areas of adjacent two sub-devices in a same light-emitting device on the base plate, and an orthographic projection of the second defining portion on the base plate is located between orthographic projections of light-emitting areas of adjacent two light-emitting devices on the base plate; the first defining portion comprises a first defining segment, and an orthographic projection of the first defining segment on the base plate overlaps the orthographic projection of the first touch segment on the base plate; the second defining portion comprises a second defining segment, and an orthographic projection of the second defining segment on the base plate overlaps the orthographic projection of the second touch segment on the base plate.

7. The display panel of claim 6, wherein a width of the orthographic projection of the second defining segment on the base plate is greater than a width of the orthographic projection of the first defining segment on the base plate.

8. The display panel of claim 6, wherein orthographic projections of light-emitting areas of the sub-devices in a same light-emitting device on the base plate are distributed axially symmetrically about an orthographic projection of a central axis of the first defining segment on the base plate.

9. The display panel of claim 6, wherein the first defining portion further comprises a third defining segment, an orthographic projection of the third defining segment on the base plate does not overlap the orthographic projection of the touch portion on the base plate, and a width of the orthographic projection of the first defining segment on the base plate and a width of the orthographic projection of the second defining segment on the base plate are both greater than a width of the orthographic projection of the third defining segment on the base plate.

10. The display panel of claim 6, wherein the second defining portion further comprises a fourth defining segment, an orthographic projection of the fourth defining segment on the base plate does not overlap the orthographic projection of the touch portion on the base plate, and a width of the orthographic projection of the first defining segment on the base plate and a width of the orthographic projection of the second defining segment on the base plate are both greater than a width of the orthographic projection of the fourth defining segment on the base plate.

11. The display panel of claim 6, wherein the base plate comprises a substrate, a first insulating layer arranged at a side of the substrate towards the light-emitting device, and a transistor arranged between the substrate and the first insulating layer, the first insulating layer comprises a through hole, the first electrode is electrically connected with the transistor through the through hole, and an orthographic projection of at least one through hole on the substrate is located within an orthographic projection of the first defining portion or the second defining portion on the substrate.

12. The display panel of claim 11, wherein an orthographic projection of at least one through hole on the substrate is located within an orthographic projection of the touch portion on the substrate; and
an orthographic projection of at least one through hole on the substrate is located within an orthographic projection of the first touch segment on the substrate.

13. The display panel of claim 11, wherein orthographic projections of light-emitting areas of at least two sub-devices in a same light-emitting device on the substrate are distributed centrally symmetrically about a centroid of an orthographic projection of the through hole on the substrate.

14. The display panel of claim 11, wherein the display panel further comprises a connection structure arranged in the same layer as the first electrode and located between the first electrodes of the at least two sub-devices in a same light-emitting device, and the first electrodes of the at least two sub-devices in a same light-emitting device are electrically connected through the connection structure; and
the orthographic projection of the touch portion on the base plate partially overlaps an orthographic projection of the connection structure on the base plate.

15. The display panel of claim 4, wherein the display panel further comprises an isolation structure arranged at one side of the base plate and forming an isolation opening communicated with the pixel opening, and a portion of an orthographic projection of the isolation structure on the base plate is located between orthographic projections of light-emitting areas of adjacent two sub-devices in a same light-emitting device on the base plate;
the touch electrode is arranged at a side of the isolation structure away from the base plate;
the orthographic projection of the touch portion on the base plate is located within the orthographic projection of the isolation structure on the base plate;
the isolation structure comprises a first isolation portion and a second isolation portion located at a side of the first isolation portion away from the base plate, and the second isolation portion protrudes from the first isolation portion towards the isolation opening;
the isolation structure comprises conductive material, and the second electrode is connected with the isolation structure;
the isolation structure is arranged at a side of the pixel defining portion away from the base plate; and
the base plate comprises a substrate, a first insulating layer arranged at a side of the substrate towards the light-emitting device, and a transistor arranged between the substrate and the first insulating layer, the first insulating layer comprises a through hole, the first electrode is electrically connected with the transistor through the through hole, and an orthographic projection of at least one through hole on the substrate is located within an orthographic projection of the isolation structure on the substrate.

16. The display panel of claim 2, wherein the light-emitting device comprises a first light-emitting device, a second light-emitting device, and a third light-emitting device emitting lights of different colors, and at least one of the first light-emitting device, the second light-emitting device, and the third light-emitting device comprises at least two sub-devices.

17. The display panel of claim 16, wherein the first light-emitting device emits green light, the second light-emitting device emits red light, and the third light-emitting device emits blue light.

18. The display panel of claim 16, wherein an area of a light-emitting area of the third light-emitting device is greater than or equal to an area of a light-emitting area of the second light-emitting device, and the area of the light-emitting area of the second light-emitting device is greater than or equal to an area of a light-emitting area of the first light-emitting device; and
a number of sub-devices in the first light-emitting device, a number of sub-devices in the second light-emitting device, and a number of sub-devices in the third light-emitting device are all equal, or the number of sub-devices in the first light-emitting device is less than the number of sub-devices in the third light-emitting device.

19. The display panel of claim 16, wherein the third light-emitting device comprises at least two sub-devices, and at least a portion of the orthographic projection of the first touch segment on the base plate is located between orthographic projections of light-emitting areas of adjacent two sub-devices in the third light-emitting device on the base plate.

20. The display panel of claim 19, wherein the base plate comprises a substrate, a first insulating layer arranged at a side of the substrate towards the light-emitting device, and a transistor arranged between the substrate and the first insulating layer, the first insulating layer comprises a through hole comprising a third via, the first electrode in the third light-emitting device is electrically connected with the transistor through the third via, and an orthographic projection of the third via on the substrate is located between orthographic projections of light-emitting areas of adjacent two sub-devices in the third light-emitting device on the substrate.

21. The display panel of claim 19, wherein the first light-emitting device and the second light-emitting device each comprise at least two sub-devices, the orthographic projection of the first touch segment on the base plate is not located between orthographic projections of light-emitting areas of adjacent two sub-devices in the first light-emitting device on the base plate, and a portion of the orthographic projection of the first touch segment on the base plate is located between orthographic projections of light-emitting areas of adjacent two sub-devices in the second light-emitting device on the base plate.

22. The display panel of claim 21, wherein at least a portion of the orthographic projection of the second touch segment on the base plate is located between orthographic projections of light-emitting areas of the first light-emitting device and the second light-emitting device that are adjacent on the base plate, or at least a portion of the orthographic projection of the second touch segment on the base plate is located between orthographic projections of light-emitting areas of the first light-emitting device and the third light-emitting device that are adjacent on the base plate, or at least a portion of the orthographic projection of the second touch segment on the base plate is located between orthographic projections of light-emitting areas of the second light-emitting device and the third light-emitting device that are adjacent on the base plate; and
the base plate comprises a substrate, a first insulating layer arranged at a side of the substrate towards the light-emitting device, and a transistor arranged between the substrate and the first insulating layer, the first insulating layer comprises a through hole comprising a first via and a second via, the first electrode in the first light-emitting device is electrically connected with the transistor through the first via, and the first electrode in the second light-emitting device is electrically connected with the transistor through the second via,
an orthographic projection of the first via on the substrate is not located between orthographic projections of light-emitting areas of adjacent two sub-devices in the first light-emitting device on the substrate, and an orthographic projection of the second via on the substrate is located between orthographic projections of light-emitting areas of adjacent two sub-devices in the second light-emitting device on the substrate.

23. The display panel of claim 19, wherein the first light-emitting device and the second light-emitting device each comprise at least two sub-devices, a portion of the orthographic projection of the first touch segment on the base plate is located between orthographic projections of light-emitting areas of adjacent two sub-devices in the first light-emitting device on the base plate, and a portion of the orthographic projection of the first touch segment on the base plate is located between orthographic projections of light-emitting areas of adjacent two sub-devices in the second light-emitting device on the base plate.

24. The display panel of claim 23, wherein a first gap is between light-emitting areas of the first light-emitting device and the second light-emitting device that are adjacent, and at least a portion of an orthographic projection of the first gap on the base plate does not overlap the orthographic projection of the second touch segment on the base plate; and
at least a portion of the orthographic projection of the second touch segment on the base plate is located between orthographic projections of light-emitting areas of the first light-emitting device and the third light-emitting device that are adjacent on the base plate; or at least a portion of the orthographic projection of the second touch segment on the base plate is located between orthographic projections of light-emitting areas of the second light-emitting device and the third light-emitting device that are adjacent on the base plate; or a second gap is further between light-emitting areas of the first light-emitting device and the second light-emitting device that are adjacent, and at least a portion of the orthographic projection of the second touch segment on the base plate overlaps an orthographic projection of the second gap on the base plate.

25. The display panel of claim 23, wherein the base plate comprises a substrate, a first insulating layer arranged at a side of the substrate towards the light-emitting device, and a transistor arranged between the substrate and the first insulating layer, the first insulating layer comprises a through hole comprising a first via and a second via, the first electrode in the first light-emitting device is electrically connected with the transistor through the first via, and the first electrode in the second light-emitting device is electrically connected with the transistor through the second via; and
an orthographic projection of the first via on the substrate is located between orthographic projections of light-emitting areas of adjacent two sub-devices in the first light-emitting device on the substrate, or an orthographic projection of the second via on the substrate is located between orthographic projections of light-emitting areas of adjacent two sub-devices in the second light-emitting device on the substrate.

26. The display panel of claim 19, wherein the second light-emitting device comprises at least two sub-devices, and the orthographic projection of the first touch segment on the base plate is not located between orthographic projections of light-emitting areas of adjacent two sub-devices in the second light-emitting device on the base plate; and
the base plate comprises a substrate, a first insulating layer arranged at a side of the substrate towards the light-emitting device, and a transistor arranged between the substrate and the first insulating layer, the first insulating layer comprises a through hole comprising a second via, the first electrode in the second light-emitting device is electrically connected with the transistor through the second via, and an orthographic projection of the second via on the substrate is not located between orthographic projections of light-emitting areas of adjacent two sub-devices in the second light-emitting device on the base plate.

27. The display panel of claim 16, wherein the second light-emitting device and the third light-emitting device each comprise at least two sub-devices, the orthographic projection of the first touch segment on the base plate is not located between orthographic projections of light-emitting areas of adjacent two sub-devices in the third light-emitting device on the base plate, and a portion of the orthographic projection of the first touch segment on the base plate is located between orthographic projections of light-emitting areas of adjacent two sub-devices in the second light-emitting device on the base plate; and
the base plate comprises a substrate, a first insulating layer arranged at a side of the substrate towards the light-emitting device, and a transistor arranged between the substrate and the first insulating layer, the first insulating layer comprises a through hole comprising a second via and a third via, the first electrode in the second light-emitting device is electrically connected with the transistor through the second via, and the first electrode in the third light-emitting device is electrically connected with the transistor through the third via,
an orthographic projection of the second via on the substrate is located between orthographic projections of light-emitting areas of adjacent two sub-devices in the second light-emitting device on the base plate, and an orthographic projection of the third via on the substrate is not located between orthographic projections of light-emitting areas of adjacent two sub-devices in the third light-emitting device on the base plate.

28. The display panel of claim 16, wherein the first light-emitting device comprises at least two sub-devices, and the orthographic projection of the first touch segment on the base plate is not located between orthographic projections of light-emitting areas of adjacent two sub-devices in the first light-emitting device on the base plate; and
the base plate comprises a substrate, a first insulating layer arranged at a side of the substrate towards the light-emitting device, and a transistor arranged between the substrate and the first insulating layer, the first insulating layer comprises a through hole comprising a first via, the first electrode in the first light-emitting device is electrically connected with the transistor through the first via, and an orthographic projection of the first via on the substrate is not located between orthographic projections of light-emitting areas of adjacent two sub-devices in the first light-emitting device on the base plate.

29. The display panel of claim 16, wherein one first light-emitting device, two second light-emitting devices, and two third light-emitting devices form a pixel group, the pixel groups are distributed in an arrayed along a first direction and a second direction; in a single pixel group, the first light-emitting device is located within a virtual quadrilateral, two opposite vertices of the virtual quadrilateral coincide with centers of the two second light-emitting devices, respectively, and the other two opposite vertices of the virtual quadrilateral coincide with centers of the two third light-emitting devices, respectively; and the first direction intersects the second direction.

30. The display panel of claim 16, wherein a plurality of first light-emitting devices are distributed along a second direction in sequence to form a first pixel column, a plurality of second light-emitting devices are distributed along the second direction in sequence to form a second pixel column, a plurality of third light-emitting devices are distributed along the second direction in sequence to form a third pixel column, and the second pixel column, the first pixel column, and the third pixel column are distributed alternately along a first direction in sequence, wherein the first direction intersects the second direction; or
a plurality of first light-emitting devices and a plurality of second light-emitting devices are distributed alternately along the second direction to form a fourth pixel column, a plurality of third light-emitting devices are distributed along the second direction in sequence to form a fifth pixel column, and the fourth pixel column and the fifth pixel column are distributed alternately along the first direction in sequence, wherein the first direction intersects the second direction.
